(19) United States
(12) Patent Application Publication
(10) Pub. No.: US 2012/0318346 A1
(43) Pub. Date: Dec. 20, 2012

(54) METHOD OF MANUFACTURING PHOTOELECTRIC CONVERSION ELEMENT, PHOTOELECTRIC CONVERSION ELEMENT, AND ELECTRONIC APPARATUS

(75) Inventors: Hiroko Miyashita, Kanagawa (JP); Yuto Takagi, Kanagawa (JP); Masahiro Morooka, Kanagawa (JP); Shinichiro Morikawa, Kanagawa (JP)

(73) Assignee: Sony Corporation, Tokyo (JP)

(21) Appl. No.: 13/427,036

(22) Filed: Mar. 22, 2012

(30) Foreign Application Priority Data
Mar. 31, 2011 (JP) 2011-078413

(51) Int. Cl. H01L 31/0224; H01L 31/18

(52) U.S. Cl. 136/256; 438/98; 257/E31.124

(57) ABSTRACT

A method of manufacturing a photoelectric conversion element includes: forming a current-collecting wiring with a conductive paste containing therein silver particles and a low-melting point glass frit on a transparent conductive substrate when the photoelectric conversion element having a structure in which an electrolyte layer is provided between a porous electrode on the transparent conductive substrate, and a counter substrate is manufactured.

### BACKGROUND

The present disclosure relates to a method of manufacturing a photoelectric conversion element, the photoelectric conversion element, and an electronic apparatus. In particularly, the present disclosure related to a method of manufacturing a photoelectric conversion element which is suitable for being used in a dye-sensitized solar cell, the photoelectric conversion element, and an electronic apparatus including the photoelectric conversion element.

Since a solar cell as a photoelectric conversion element for converting a solar light into an electrical energy uses the solar light as an energy source, an influence exerted on the global environment is very small, and thus further popularization of the solar cell is expected.

Heretofore, a crystalline silicon system solar cell using single crystalline or polycrystalline silicon, and an amorphous silicon system solar cell have been mainly used as the solar cells.

On the other hand, a dye-sensitized solar cell which was proposed in 1991 by Michael Gratzel et al. has attracted attention because a high photoelectric conversion efficiency can be obtained, the dye-sensitized solar cell can be manufactured at a low cost without requiring large scale equipment during the manufacture unlike any of the existing silicon system solar cells, and so forth. This technique, for example, is described in a Non-Patent Document of Nature, 353, pp. 737 to 740, 1991.

The dye-sensitized solar cell generally has a structure in which a porous electrode made of a titanium oxide or the like having photosensitized dyes coupled thereto and formed on a transparent conductive substrate, and a counter electrode are made to face each other, and an electrolyte layer is filled in a space defined between the porous electrode and the counter electrode. An electrolytic solution obtained by dissolving an electrolyte containing therein redox species such as iodine or iodide ions in a solvent is used as the electrolytic solution for the dye-sensitized solar cell in many cases.

In the dye-sensitized solar cell, normally, a current-collecting wiring for collecting the electrons caused to flow from the porous electrode into the transparent conductive substrate underlying the porous electrode in a phase of an operation is formed on the transparent conductive substrate. With regard to a method of forming the current-collecting wiring, a method of applying a silver (Ag) paste onto a transparent conductive substrate and solidifying the Ag paste, thereby forming the current-collecting wiring is simple and thus is frequently used.

However, according to the knowledge of the inventors of this application, when the current-collecting wiring is made with the Ag paste, the following problem is caused. That is to say, for the dye-sensitized solar cell, after the current-collecting wiring composed of silver particles is made with the silver paste on the transparent conductive substrate, a titanium oxide paste containing therein titanium oxide fine particles is applied onto the transparent conductive substrate, and the titanium oxide paste is fired at a temperature of about 500° C., thereby forming the porous electrode made of the titanium oxide. However, in the phase of the firing, the silver particles composing the current-collecting wiring flow and the current-collecting wiring flows in turn. As a result, silver contacts the porous electrode to reduce the porous electrode, and the flowing silver causes the long-term reliability of the dye-sensitized solar cell to become worse.

The present disclosure has been made in order to solve the problems described above, and it is therefore desirable to provide a method of manufacturing a photoelectric conversion element with which silver particles composing a current-collecting wiring can be effectively prevented from flowing when a porous electrode is formed through firing, and thus prevention of deterioration of the porous electrode and enhancement of long-term reliability can be realized, the photoelectric conversion element, and an electronic apparatus including the excellent photoelectric conversion element.

The desire described above and other desires will be made clear from the description in this specification taken in conjunction with the accompanying drawings.

In order to attain the desire described above, according to an embodiment of the present disclosure, there is provided a method of manufacturing a photoelectric conversion element including: forming a current-collecting wiring with a conductive paste containing therein silver particles and a low-melting point glass frit on a transparent conductive substrate when the photoelectric conversion element having a structure in which an electrolyte layer is provided between a porous electrode on the transparent conductive substrate, and a counter substrate is manufactured.

According to another embodiment of the present disclosure, there is provided a photoelectric conversion element having a structure in which an electrolyte layer is provided between a porous electrode on a transparent conductive substrate, and a counter substrate, in which a current-collecting wiring made with a conductive paste containing therein metal particles and a low-melting point glass frit is provided on the transparent conductive substrate.

According to still another embodiment of the present disclosure, there is provided an electronic apparatus including: at least one photoelectric conversion element having a structure in which an electrolyte layer is provided between a porous electrode on a transparent conductive substrate, and a counter substrate, in which a current-collecting wiring made with a conductive paste containing therein metal particles and a low-melting point glass frit is provided on the transparent conductive substrate.

In the present disclosure, in general, a softening point of the low-melting point glass frit is from 360° C. to 500° C., and is preferably from 380° C. to 480° C. A concrete example of the low-melting point glass frit, for example, includes a glass frit containing therein a bismuth oxide, a boron oxide, a zinc oxide, and an aluminum oxide each having a softening point from 380° C. to 400° C., a glass frit containing therein a bismuth oxide, a zinc oxide, and a boron oxide each having a softening point from 440° C. to 460° C., a glass frit containing therein a bismuth oxide, a boron oxide, a zinc oxide, a copper oxide, and a silicon oxide each having a softening point from 450° C. to 470° C., a glass frit containing therein a bismuth oxide, a zinc oxide, a boron oxide, and a silicon oxide each having a softening point from 460° C. to 480° C., and the like. However, the present disclosure is by no means limited to these glass frits.

The photoelectric conversion element is typically a dye-sensitized photoelectric conversion element in which a photosensitized dye is coupled to (or absorbed on) the porous electrode. In this case, the method of manufacturing the photoelectric conversion element typically further includes a process for coupling the photosensitized dye to the porous electrode. The porous electrode is typically composed of a fine particle made of a semiconductor. The semiconductor preferably includes a titanium oxide (TiO₂), especially, an anatase type TiO₂.

An electrode composed of the fine particle having a so-called core-shell structure may be used as the porous electrode. In this case, the photosensitized dye may not be necessarily coupled to the porous electrode. An electrode composed of fine particles each composed of a core made of a metal and a shell composed of a metal oxide surrounding the core is preferably used as the porous electrode. The using of such a porous electrode results in that when the porous electrode or the like is impregnated with the electrolytic solution, the electrolyte of the electrolytic solution does not contact the core made of the metal of the metal/metal oxide fine particles. Therefore, the porous electrode can be effectively prevented from being dissolved due to the electrolyte. For this reason, gold (Au), silver (Ag), copper (Cu) or the like which has been difficult to use in the past, and which has a large effect of surface plasmon resonance can be used as the metal composing the core of the metal/metal oxide fine particles. As a result, the effect of the surface plasmon resonance can be sufficiently obtained in the photoelectric conversion. In addition, an iodine system electrolyte can be used as the electrolyte of the electrolytic solution. Platinum (Pt), palladium (Pd) or the like can be used as the metal composing the core of the metal/metal oxide fine particles. A metal oxide which is not dissolved in the electrolyte used is used as the metal oxide composing the shell of the metal/metal oxide fine particles, and is selected as may be necessary. Although at least one kind of metal oxide selected from the group consisting of a titanium oxide (TiO₂), a tin oxide (SnO₂), a niobium oxide (Nb₂O₅), and a zinc oxide (ZnO) is used as such a metal oxide, the present disclosure is by no mean limited thereto. For example, a metal oxide such as a tungsten oxide (WO₃) or a strontium titanate (SrTiO₃) can also be used. Although a particle size of the fine particle is suitably selected, preferably, the particle size of the fine particle is set in the range of 1 to 500 nm. In addition, although a particle size of the core of the fine particle is suitably selected, preferably, the particle size of the core of the fine particle is set in the range of 1 to 200 nm.

When the transparent conductive substrate is composed of a substrate in which a transparent conductive layer made of a fluorine-doped tin oxide (FTO) is provided on a transparent substrate, preferably, the current-collecting wiring is provided on the transparent conductive substrate through a conductive adhesion layer. Although such an adhesion layer, preferably, is made of at least one kind of metal selected from the group consisting of silver, gold, platinum, titanium, chromium, aluminum, and copper, the present disclosure is by no means limited thereto.

As may be necessary, the current-collecting wiring, for example, is composed of a bus electrode and plural finger electrodes branching off from the bus electrode, and when let t (m) be a width of at least one finger electrode, t may fulfill the following expression. As a result, a balance between the power-collecting performance of the finger electrodes and an aperture ratio of the porous electrode can be optimized, and thus an output from the photoelectric conversion element can be maximized.

$$t = {d}_{0} {i}_{0} y \times \sqrt{\frac{{ρ}_{0}}{{h}_{0} {W}_{0}}}$$

where d₀ is a power generation electrode width (finger electrode interval) (m), i₀ is a rated power generation current density (A/m²), y is a distance (m) from a terminal of the finger electrode, ρ₀ is volume resistivity (Ωm) of a material of the finger electrode, h₀ is a thickness (m) of the finger electrode, and W₀ is a generated power output density (W/m²).

Or, the current-collecting wiring has a fine power-collecting electrode structure, specifically, the current-collecting wiring is composed of a bus electrode and plural stripe electrodes branching off from the bus electrode, and when let d₀ (m) be a pitch of the stripe electrodes, d₀ may fulfill the following expression. As a result, the balance between the power-collecting performance of the stripe electrodes and an aperture ratio of the stripe electrodes can be optimized, and thus an output from the photoelectric conversion element can be maximized.

$${d}_{0} = \sqrt{\frac{3 t {W}_{0}}{{R}_{0} {i}_{0}^{2} {l}^{2}} + {t}^{2}}$$

where t is a width (m) of the stripe electrode, W₀ is a rated generated power output density (W/m²), R₀ is a line resistance (Ω/m) of the stripe electrode, i₀ is a rated power generation current density (A/m²), and l is a power-collecting distance (m) of the stripe electrode.

Or, the current-collecting wiring has a fine power-collecting electrode structure, specifically, the current-collecting wiring is composed of a bus electrode, and a mesh electrode or a grid electrode electrically connected to the bus electrode, and when let Ap be an aperture ratio of the mesh electrode or the grid electrode, Ap may fulfill the following expression. As a result, a balance between the power-collecting performance of the mesh electrode or the grid electrode, and an aperture ratio of the mesh electrode or the grid electrode can be optimized, and an output from the photoelectric conversion element can be maximized.

$$Ap = \frac{1}{\sqrt{\frac{3 t {W}_{0}}{{R}_{0} {i}_{0}^{2} {l}^{2} {t}^{2}} + 1}}$$

where t is a width (m) of the stripe electrode, W₀ is a rated generated power output density (W/m²), R₀ is a line resistance (Q/m) of the stripe electrode, i₀ is a rated generated power current density (A/m²), and 1 is a power-collecting distance (m) of the stripe electrode.

The photoelectric conversion element is most typically structured as the solar cell. However, the photoelectric conversion element may also be an element other than the solar cell, for example, an optimal sensor or the like.

The photoelectric conversion element can be used as a power source for various kinds of electronic apparatuses. The electronic apparatus may be basically any kind of one, and includes both of a mobile type one and a stationary type one. Concrete examples are given as a mobile phone, a mobile apparatus, a robot, a personal computer, a car-mounted apparatus, various kinds of home electric appliances, and the like. In this case, the photoelectric conversion element, for example, is the solar cell used as the power source for each of these electronic apparatuses.

According to an embodiment of the present disclosure, the conductive paste contains therein the low-melting point glass frit in addition to the silver particles, whereby when the firing for forming the porous electrode is carried out after the current-collecting wiring has been formed with the conductive paste, the low-melting point glass frit flows earlier than the silver particles composing the power collecting wiring. As a result, it is possible to suppress the flowing of the silver particles composing the power collecting wiring.

As set forth hereinabove, according to an embodiment of the present disclosure, it is possible to realize the method of manufacturing the photoelectric conversion element with which it is possible to effectively prevent the silver particles composing the power collecting wiring from flowing when the porous electrode is formed through the firing, and thus it is possible to realize the prevention of the deterioration of the porous electrode, and the enhancement of the long-term reliability, and the photoelectric conversion element concerned. Also, it is possible to obtain the high-performance electronic apparatus including the photoelectric conversion element concerned.

### BRIEF DESCRIPTION OF THE DRAWINGS

FIG. 1 is a cross sectional view showing a structure of a dye-sensitized photoelectric conversion element according to a first embodiment of the present disclosure;

FIGS. 2A and 2B are respectively schematic diagrams showing pattern shapes of a current-collecting wiring in the dye-sensitized photoelectric conversion element according to the first embodiment of the present disclosure;

FIGS. 3A to 3D are respectively schematic diagrams showing pattern shapes of the current-collecting wiring in the dye-sensitized photoelectric conversion element according to the first embodiment of the present disclosure;

FIGS. 4A to 4D are respectively photographs substituted for drawings showing results of evaluations of a conductive paste containing therein Ag particles and a low-melting point glass frit;

FIG. 5 is a cross sectional view showing a dye-sensitized photoelectric conversion element according to a second embodiment of the present disclosure;

FIGS. 6A, 6B, and 6C are respectively a schematic diagram, and graphical representations explaining optimization of a finger electrode in a dye-sensitized photoelectric conversion element according to a third embodiment of the present disclosure;

FIG. 7 is a schematic diagram explaining the optimization of the finger electrode in the dye-sensitized photoelectric conversion element according to the third embodiment of the present disclosure;

FIG. 8 is another schematic diagram explaining the optimization of the finger electrode in the dye-sensitized photoelectric conversion element according to the third embodiment of the present disclosure;

FIG. 9 is a schematic diagram showing a result of carrying out a wiring simulation for evaluating the finger electrode before the optimization in the dye-sensitized photoelectric conversion element according to the third embodiment of the present disclosure;

FIG. 10 is a schematic diagram showing a result of carrying out a wiring simulation for evaluating the finger electrode after the optimization in the dye-sensitized photoelectric conversion element according to the third embodiment of the present disclosure;

FIGS. 11A, 11B, and 11C are respectively graphs showing results of evaluations for the dye-sensitized photoelectric conversion element according to the third embodiment of the present disclosure;

FIG. 12 is a schematic diagram explaining optimization of a width of a stripe electrode in a dye-sensitized photoelectric conversion element according to a fourth embodiment of the present disclosure;

FIG. 13 is another schematic diagram explaining the optimization of the width of the stripe electrode in the dye-sensitized photoelectric conversion element according to the fourth embodiment of the present disclosure;

FIG. 14 is a graph showing a relationship between an aperture ratio of a grid electrode, and a generated power output in a dye-sensitized photoelectric conversion element according to a fifth embodiment of the present disclosure;

FIG. 15 is another graph showing the relationship between the aperture ratio of the grid electrode, and the generated power output in the dye-sensitized photoelectric conversion element according to the fifth embodiment of the present disclosure;

FIG. 16 is a schematic diagram showing a pattern shape of a current-collecting wiring in the dye-sensitized photoelectric conversion element according to the fifth embodiment of the present disclosure; and

FIG. 17 is a cross sectional view showing a structure of a metal/metal oxide fine particles composing a porous electrode in a dye-sensitized photoelectric conversion element according to a sixth embodiment of the present disclosure.

### DETAILED DESCRIPTION OF THE PREFERRED EMBODIMENTS

Embodiments of the present disclosure will be described in detail hereinafter with reference to the accompanying drawings. It is noted that the description will be given below in accordance with the following order:

1. First Embodiment (a dye-sensitized photoelectric conversion element and a method of manufacturing the same);

2. Second Embodiment (a dye-sensitized photoelectric conversion element and a method of manufacturing the same);

3. Third Embodiment (a dye-sensitized photoelectric conversion element and a method of manufacturing the same);

4. Fourth Embodiment (a dye-sensitized photoelectric conversion element and a method of manufacturing the same);

5. Fifth Embodiment (a dye-sensitized photoelectric conversion element and a method of manufacturing the same);

6. Sixth Embodiment (a dye-sensitized photoelectric conversion element and a method of manufacturing the same);

7. Seventh Embodiment (a photoelectric conversion element and a method of manufacturing the same); and

8. Eighth Embodiment (an electronic apparatus).

### 1. First Embodiment

### Dye-Sensitized Photoelectric Conversion Element

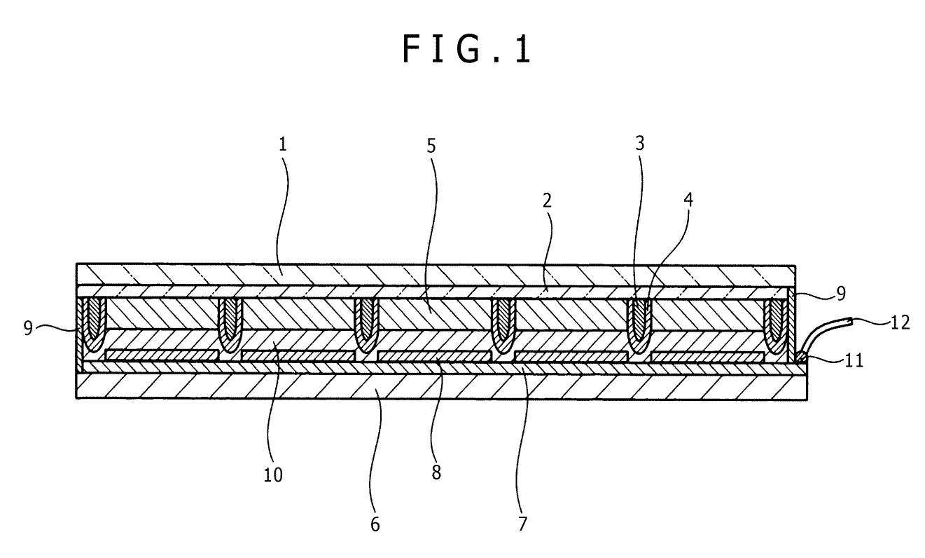

FIG. 1 is a cross sectional view showing a structure of a dye-sensitized photoelectric conversion element according to a first embodiment of the present disclosure.

As shown in FIG. 1, in the dye-sensitized photoelectric conversion element, a transparent conductive layer 2 is provided on one principal surface of a transparent substrate 1. A current-collecting wiring 3 is provided in a predetermined pattern shape on the transparent conductive layer 2. A protective layer 4 is provided so as to cover the current-collecting wiring 3. Corrosion of the current-collecting wiring 3 caused by an electrolytic solution which will be described later can be prevented by the protective layer 4. A porous electrode 5 is provided on the transparent conductive layer 2. The porous electrode 5 either may be provided on a portion other than the current-collecting wiring 3 or may be provided so as to be piled on the current-collecting wiring 3. In FIG. 1, however, the case where the porous electrode 5 is provided on the portion other than the current-collecting wiring 3 is exemplified. One or plural kinds of photosensitized dyes (not shown) are coupled to the porous electrode 3. On the other hand, a conductive layer 7 is provided on one principal surface of the substrate 6. A counter electrode 8 is provided on the conductive layer 7 so as to face the porous electrode 3 on the transparent conductive layer 2. Also, outer peripheral portions of the transparent substrate 1 and a counter electrode 8 are encapsulated with an encapsulating material 9. Also, an electrolyte layer 10 is provided between the porous electrode 3 on the transparent conductive layer 2, and the counter electrode 8. An electrode 11 is provided on an end portion of the conductive layer 7, and an external wiring 12 is connected to the electrode 11. Although an illustration is omitted here, the external wiring is connected to an end portion as well on the transparent conductive layer 2.

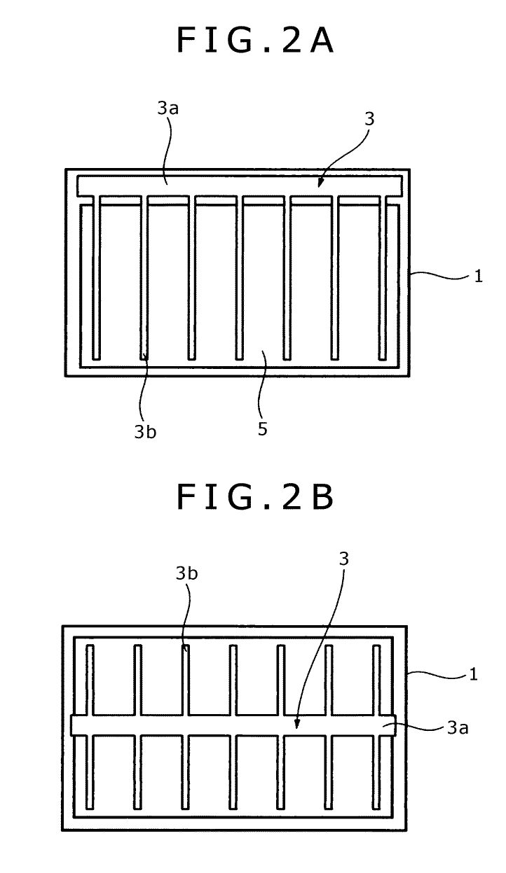

FIGS. 2A and 2B show examples of a pattern shape of the current-collecting wiring 3, respectively. In the example shown in FIG. 2A, the current-collecting wiring 3 is composed of a bus electrode 3a and plural finger electrodes 3b. In this case, the bus electrode 3a is provided along one side of the transparent substrate 1. Also, the plural finger electrodes 3b branch off from the bus electrode 3a. In the example shown in FIG. 2B, the current-collecting wiring 3 is composed of the bus electrode 3a provided at the central portion of the transparent substrate 1 and the plural finger electrodes 3b branching off from the bus electrode 3a to the both sides. The finger electrodes 3b are provided in order to efficiently collect a current generated through the power generation in the porous electrode 5, whereas the bus electrode 3a is provided in order to efficiently collect the current collected by the finger electrodes 3b to take out the current thus collected to the outside.

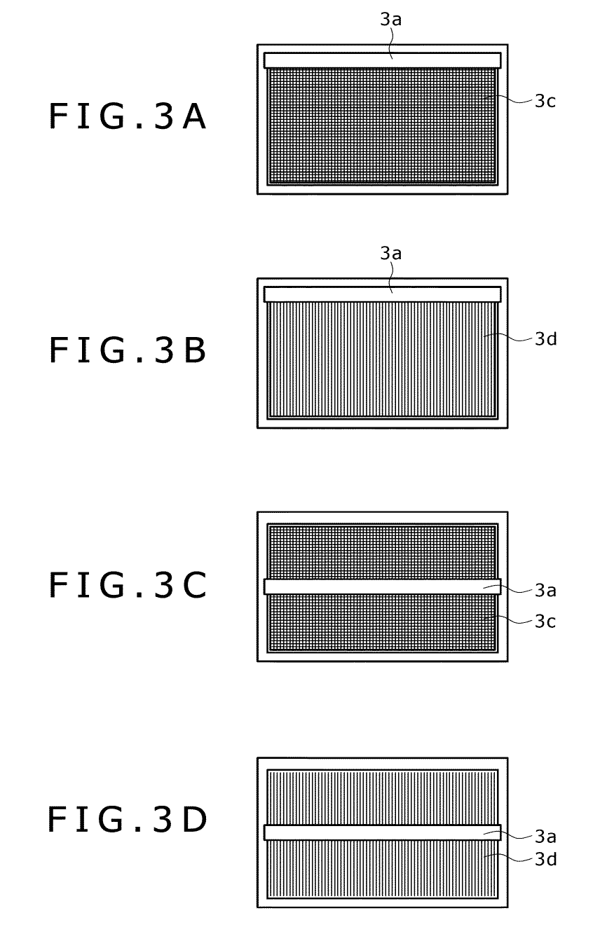

The current-collecting wiring 3 may adopt a fine power-collecting electrode structure. FIGS. 3A to 3D show examples of a pattern shape of the fine power-collecting electrode structure. In the example shown in FIG. 3A, the current-collecting wiring 3 is composed of a bus electrode 3a provided along one side of the transparent substrate 1, and a grid electrode 3c (or a mesh electrode) electrically connected to the bus electrode 3a. In the example shown in FIG. 3B, the current-collecting wiring 3 is composed of the bus electrode 3a provided along one side of the transparent substrate 1, and plural stripe electrodes 3d branching off from the bus electrode 3a. In the example shown in FIG. 3C, the current-collecting wiring 3 is composed of the bus electrode 3a provided along the central portion of the transparent substrate 1, and the grid electrode 3c provided on both sides of the bus electrode 3a and electrically connected to the bus electrode 3a. In the example shown in FIG. 3D, the current-collecting wiring 3 is composed of the bus electrode 3a provided along one side of the transparent substrate 1, and the plural stripe electrodes 3d branching off to both sides of the bus electrode 3a. Each of the grid electrode 3c and the stripe electrode 3d is provided in order to effectively collect the current generated through the power generation in the porous electrode 5, whereas the bus electrode 3a is provided in order to effectively collect the current thus collected to take out the current thus collected to the outside.

After the conductive paste containing therein the Ag particles and the low-melting point glass frit has been applied onto the transparent conductive layer 2, the conductive paste thus applied is solidified, thereby forming the current-collecting wiring 3. The low-melting point glass frit which is previously given, for example, can be used as the low-melting point glass frit in this case. Since the current-collecting wiring 3 is made with the conductive paste containing therein the Ag particles and the low-melting point glass frit, when the porous electrode 5 is heated during the firing thereof, the low-melting point glass frit flows, thereby suppressing the flowing of the Ag particles. The protective layer 4 is provided in order to protect the current-collecting wiring 3 from the electrolytic solution, and is preferably made of a transparent metal oxide such as an ITO, a SnO₂, a TiO₂ or a ZnO.

A porous semiconductor layer which is obtained by sintering semiconductor fine particles is typically used as the porous electrode 5. The photosensitized dyes adsorb on the surfaces of the semiconductor fine particles. An element semiconductor typified by silicon, a compound semiconductor, a semiconductor having a perovskite structure, or the like can be used as a material for the semiconductor fine particle. Any of these semiconductors is preferably an n-type semiconductor in which the electrons in a conduction band become carriers under photoexcitation to generate an anode current. Specifically, for example, a semiconductor such as a titanium oxide (TiO₂), a zinc oxide (ZnO), a tungsten oxide (WO₃), a niobium oxide (Nb₂O₅), a strontium titanate (SrTiO₃) or a tin oxide (SnO₂) is used as the material for the porous electrode 5. Of these semiconductors, TiO₂, especially, an anatase type TiO₂ is preferably used. However, the kinds of semiconductors are by no means limited thereto, and two or more kinds of semiconductors can be used after either mixing or composition as may be necessary. In addition, a shape of the semiconductor fine particle may be any of a grain-like shape, a tube-like shape, a rod-like shape or the like.

Although there is not especially a limit to the particle size of the semiconductor fine particle, an average particle size of a primary particle is set in the range of 1 to 200 nm, and is more preferably set in the range of 5 to 100 nm. In addition, the particles each having a particle size larger than that of each of the semiconductor fine particles are mixed with one another, and an incident light is scattered by the particles, thereby also making it possible to increase a quantum yield. In this case, although an average particle size of the particles with which the semiconductor fine particles are specially mixed is preferably set in the range of 20 to 500 nm, the present disclosure is by no means limited thereto.

A porous electrode having an actual surface area including surface areas of fine particle surfaces facing internal holes of the porous semiconductor layer composed of the semiconductor fine particles is preferable as the porous electrode 5 so that as many photosensitized dyes as possible can be coupled to one another. For this reason, the actual surface area in a state in which the porous electrode 5 is formed on the transparent conductive layer 2 is preferably 10 times or more as large as an area (projected area) of an outside surface of the porous electrode 5, and is more preferably 100 times or more as large as the area (projected area) of the outside surface of the porous electrode 5. Although there is not especially a limit to this ratio, normally, this ratio is about 1,000.

In general, since the actual surface area is increased and an amount of photosensitized dyes capable of being held in a unit projected area is increased as the thickness of the porous electrode 5 is further increased and the number of semiconductor fine particles contained in the unit projected area is further increased, the light absorption factor becomes large. On the other hand, when the thickness of the porous electrode 5 is increased, a distance by which the electrons which have been moved from the photosensitized dyes to the porous electrode 5 diffuse until these electrons reach the transparent conductive layer 2 is increased. As a result, the loss in the electrons due to the electric charge recombination within the porous electrode 5 also becomes large. Therefore, although a preferable thickness exists in the porous electrode 5, this thickness is generally set in the range of 0.1 to 100 μm, more preferably set in the range of 1 to 50 μm, and is further more preferably set in the range of 3 to 30 μm.

The electrolytic solution includes a liquid solution containing therein a redox system (redox couple). Specifically, for example, a combination of iodine (I₂) and a metal or an iodine salt of an organic substance, a combination of boron (Br₂) and a metal or a bromide salt of an organic substance, or the like is used as the redox system. A cation composing a metal salt includes lithium (Li⁺), natrium (Na⁺), kalium (K⁺), cesium (Cs⁺), magnesium (Mg²⁺), calcium (Ca²⁺) or the like. In addition, a quaternary ammonium ion such as a tetraalkylammonium ion class, a pyridinium ion class or an imidazolium class is suitable as a cation composing an organic substance salt. These ion classes can be simply used or two or more kinds of ion classes mixed with one another can be used.

The electrolyte layer 10 is typically composed of an electrolytic solution, and is selected as may be necessary. However, in addition thereto, a metal complex such as a combination of a ferrocyanic acid salt and a ferricyanic acid salt, or a combination of ferrocene and a ferricinium ion, a sulfuric compound such as natrium polysulfide, or a combination of alkylthiol and alkyl disulfide, a viologen dye, or a combination of hydroquinone and quinone can also be used as the electrolytic solution.

Of the foregoing, in particular, the electrolyte obtained by combining iodine (I₂), and the quaternary ammonium compound such as a lithium iodide (LiI), a natrium iodide (NaI) or an imidazolium iodide with each other is preferable as the electrolyte of the electrolytic solution. A concentration of the electrolyte salt is preferably in the range of 0.05 to 10 M for a solvent, and is more preferably in the range of 0.2 to 3 M for the solvent. A concentration of iodine (I₂) or boron (Br₂) is preferably in the range of 0.0005 to 1 M and is more preferably in the range of 0.001 to 0.5 M.

Of the foregoing, in particular, the electrolyte obtained by combining iodine (I₂), and the quaternary ammonium compound such as a lithium iodide (LiI), a natrium iodide (NaI) or an imidazolium iodide with each other is suitable as the electrolyte of the electrolytic solution. A concentration of the electrolyte salt is preferably in the range of 0.05 to 10 M for a solvent, and is more preferably in the range of 0.2 to 3 M for the solvent. A concentration of iodine (I₂) or boron (Br₂) is preferably in the range of 0.0005 to 1 M and is more preferably in the range of 0.001 to 0.5 M. In addition, for the purpose of increasing an open voltage and a short-circuit current, it is also possible to add any of various kinds of additive agents such as a 4-tert-butylpyridine class and a benzimidazolium class.

In addition, in general, water, an alcohol class, an ether class, an ester class, a carbonate ester class, a lactone class, a carboxylate ester class, a triester phosphate class, a heterocyclic compound class, a nitryl class, a ketone class, an amide class, nitromethane, hydrocarbon halide, dimethylsulfoxide, sulfolane, N-methylpyrrolidone, 1,3-dimethylimidazolidinone, 3-methyloxazolidinone, hydrocarbon or the like is used as the solvent composing the electrolytic solution.

The transparent substrate 1 is especially by no means limited as long as the transparent substrate 1 is made of a material and has a shape through which the light is easy to transmit, and thus various kinds of substrate materials can be used. In particular, it is preferable to use the substrate material having a large transmittance for the visible light. In addition, the material is preferable which has a high cutoff performance for blocking moisture or a gas intending to enter the dye-sensitized photoelectric conversion element from the outside, and which is excellent in a solvent resistance and a weathering resistance. Specifically, the material for the transparent substrate 1 includes a transparent inorganic material such as a quartz or a glass, or a transparent plastic such as polyethyleneterephthalate, polyethylenenaphthalate, polycarbonate, polystyrene, polyethylene, polypropylene, polyphenylenesulfide, a polyvinylidene fluoride, acetylcellulose, phenoxy bromide, an aramid class, a polyimide class, a polystyrene class, a polyarylate class, a polysulfone class or a polyolefin class. A thickness of the transparent substrate 1 is especially by no means limited, and thus can be suitably selected in consideration of the light transmittance, and the performance for cutting off the inside and the outside of the photoelectric conversion element. The substrate 6 may be or may not be transparent for the light. When the transparent substrate is used as the substrate 6, a substrate similar to the transparent substrate 1 can be used as the transparent substrate. An opaque glass, a plastic, a ceramics, a metal or the like may also be used as the material for the substrate 6.

The transparent conductive layer 2 provided on the transparent substrate 1 is preferable as a sheet resistance thereof is smaller. Specifically, the sheet resistance thereof is preferably equal to or smaller than 500Ω/□, and is more preferably equal to or smaller than 100Ω/□. A known material can be used as the material composing the transparent conductive layer 2, and is selected as may be necessary. The material composing the transparent conductive layer 2, specifically, includes an indium-tin composite oxide (ITO), a fluorine-doped tin oxide (IV) SnO₂ (FTO), a tin oxide (IV) SnO₂, a zinc oxide (II) ZnO, an indium-zinc composite oxide (IZO) or the like. However, the material composing the transparent conductive layer 2 is by no means limited thereto, and thus two or more kinds of materials described above can be combined with each other to be used. The transparent layer 7 provided on the substrate 6 may be or may not be transparent for the light. When a transparent conductive layer is used as the conductive layer 7, a transparent conductive layer similar to the transparent conductive layer 2 can be used as the transparent conductive layer described above.

Although the photosensitizing dye intended to be coupled to the porous electrode 5 is especially by no means limited as long as the photosensitizing dye concerned shows the sensitizing action, a photosensitizing dye having an acid functional group which adsorbs on the surface of the porous electrode 5 is preferable. In general, a photosensitizing dye having a carboxy group, a phosphoric acid group or the like is preferable as the photosensitizing dye. Of them, the photosensitizing dye having the carboxy group is especially preferable as the photosensitizing dye. A concrete example of the photosensitizing dye includes a xanthene system dye such as Rhodamine B, Rose Bengal, eosin or erythrosine, a cyanine system dye such as merocyanine, quinocyanine or cryptocyanine, a basic dye such as phenosafranine, capri blue, thiocine or methylene blue, or a porphyrin system compound such as chlorophyll, zinc porphyrin or magnesium porphyrin. In addition thereto, a concrete example of the photosensitizing dye includes an azo dye, a phthalocyanine compound, a coumalin system compound, a bipyridine complex compound, an anthraquinone system dye, a polycyclic quinone system dye or the like. Of them, the dye of the complex whose ligand contains therein either a pyridine ring or an imidazolium ring, and whose metal is selected from the group consisting of Ru, Os, Ir, Pt, Co, Fe and Cu is preferable because the quantum yield thereof is high. In particular, a dye molecule containing therein cis-bis(isothiocyanate)-N,N-bis(2,2′-dipyridyl-4,4′-dicarboxylic acid)-ruthenium (II) or a tris(isothiocyanate)-ruthenium (II)-2,2′:6′,2″-Terpyridine-4,4′,4″-tricarboxylic acid as a basic skeleton is preferable because an absorption wavelength range thereof is wide. However, the photosensitizing dye is by no means limited thereto. Although one kind of photosensitizing dye of these photosensitizing dyes is typically used as the photosensitizing dye, two or more kinds of photosensitizing dyes may be mixed with each other to be used. When two or more kinds of photosensitizing dyes are be mixed with each other to be used, preferably, the photosensitizing dye contains an inorganic complex dye having a property for causing Metal to Ligand Change Transfer (MLCT) and held in the porous electrode 5, and an organic molecular dye having an intra-molecule Change Transfer (CT) and held in porous electrode 5. In this case, both of the inorganic complex dye and the organic molecular dye adsorb on the porous electrode 5 in the steric configurations different from each other. The inorganic complex dye preferably has either a carboxyl group or a phosphono group as the functional group which is coupled to the porous electrode 5. In addition, the organic molecular dye preferably has a carboxyl group or a phosphono group, a cyano group, an amino group, a thiol group or a thione group as the functional group which is coupled to the porous electrode 5 in the same carbon. The inorganic complex dye, for example, has a polypyridine complex. In addition, the organic molecular dye, for example, is an aromatic polycyclic conjugated system molecule having both of an electron donating group and an electron accepting group, and having the property of the intra-molecular CT.

There is not especially a limit to a method of adsorbing the photosensitizing dye on the porous electrode 5. However, the photosensitizing dye described above, for example, can be dissolved in a solvent such as an alcohol class, a nitryl class, nitromethane, a hydrocarbon halide, an ether class, dimethyl sulfoxide, an amide class, N-methylpyrrolidone, 1,3-dimethylimidazolidinone, 3-methyloxazolidinone, an ester class, a carbonate ester class, a ketone group, hydrocarbon or water, and the porous electrode 5 can be impregnated therein. Also, a liquid solution containing therein the sensitizing dyes can be applied onto the porous electrode 5. In addition, for the purpose of reducing association among the molecules of the photosensitizing dyes, a deoxycholic acid or the like may be added. An ultraviolet absorbent can also be used together therewith as may be necessary.

After the photosensitizing dyes have been adsorbed on the porous electrode 5, for the purpose of facilitating the removal of the photosensitizing dyes excessively adsorbed on the porous electrode 5, the surface of the porous electrode 5 may be treated by using an amino class. An example of the amino class includes pyridine, 4-tert-butylpyridine, polyvinylpyridine or the like. When such an amino class is the liquid, it either may be used as it is or may be dissolved in an organic solvent to be used.

When the material for the counter electrode 8 is a conductive material, any conductive material can be used. Also, when a conductive layer is formed on a side facing the electrolyte layer 10 made of an insulating material, the conductive material can also be used. With regard to the material for the counter electrode 8, it is preferable to use an electrochemically stable material. Specifically, it is preferable to use platinum, gold, carbon, a conductive polymer or the like.

In addition, for the purpose of enhancing a catalytic action for a reduction reaction in the counter electrode 8, a fine structure is preferably formed on the surface of the counter electrode 8 contacting the electrolyte layer 10 so as to increase the actual surface area. For example, in the case of platinum, the fine structure is preferably formed in a state of platinum black. Also, in the case of carbon, the fine structure is preferably formed in a state of porous carbon. The platinum black can be formed by utilizing either an anodic oxidation method for platinum or a platinic chloride treatment. In addition, the porous carbon can be formed by carrying out the sintering of the carbon fine particles or the firing of the organic polymer, or the like.

A material having a light resistance, an insulating property, and a moisture-proof property is preferably used as the material for the encapsulating material 9. A concrete example of the material for the encapsulating material 9 includes an epoxy resin, an ultraviolet curable resin, an acrylic resin, a polyisobutylene resin, ethylenevinylacetate (EVA), an ionomer resin, a ceramics, various kinds of thermal fusion bonding films or the like.

In addition, although when a liquid solution of an electrolyte composition is injected, it is necessary to provide an inlet, a place of the inlet is not especially limited except for the porous electrode 5, and a portion on the counter electrode 8 corresponding to the porous electrode 5. In addition, although a method of injecting the liquid solution of the electrolyte composition is especially by no means limited, a method is preferable in which the outer periphery is previously encapsulated, and the liquid solution of the electrolyte composition is injected into the inside of the photoelectric conversion element in which the inlet for the liquid solution is opened under a reduced pressure. In this case, a method is simple in which several droplets of the liquid solution are dropped to the inlet to be injected by utilizing the capillary phenomena. In addition, the injection of the liquid solution can also be operated either under the reduced pressure or under the heating as may be necessary. After the liquid solution has been perfectly injected, the liquid solution remaining in the inlet is removed, and the inlet is then sealed. Although there is not also especially a limit to the sealing method, a glass plate or a plastic substrate is stuck to the inlet by using a sealing agent, thereby making it possible to seal the inlet with such a member if necessary. Also, in addition to this method, like an One Drop Filling (ODF) process for a liquid crystal panel, the electrolytic solution is dropped onto the substrate, and a suitable member is stuck to the substrate under the reduced pressure, thereby making it possible to carry out the sealing. In addition, in the case of a gel-like electrolyte using polymer or the like, or a total-solid electrolyte, a polymer liquid solution containing therein the electrolyte composition, and a plasticizing agent is volatilized to be removed on the porous electrode 5 by utilizing a cast method. After the plasticizing agent has been preferably removed away, the sealing is similarly carried out by utilizing the method described above. The sealing is preferably carried out in an inactive gas ambient atmosphere or under the reduced pressure by using a vacuum sealer or the like. After sealing is carried out, for the purpose of sufficiently impregnating the electrolyte in the porous electrode 5, an operation for heating or application of pressure can also be carried out as may be necessary.

### [Method of Manufacturing Dye-Sensitized Photoelectric Conversion Element]

Next, a description will be given with respect to a method of manufacturing the dye-sensitized photoelectric conversion element.

Firstly, the transparent conductive layer 2 is formed on one principal surface of the transparent substrate 1 by utilizing a sputtering method or the like.

Next, after the conductive paste containing therein the Ag particles and the low-melting point glass frit has been applied onto the transparent conductive layer 2 so as to have the predetermined wiring pattern shape, the conductive paste is solidified, thereby forming the current-collecting wiring 3.

Next, the protective layer 4 is formed so as to cover the current-collecting wiring 3.

Next, the porous electrode 5 is formed on the transparent conductive layer 2. Although there is not especially a limit to the method of forming the porous electrode 5, when the physical property, the convenience, the manufacture cost, and the like are taken into consideration, a wet film forming method is preferably used. With regard to the wet film forming method, a method is preferable in which a paste-like dispersed liquid in which either powders or a sol of semiconductor fine particles is uniformly dispersed into a solvent such as water is prepared, and the resulting dispersed liquid is either applied onto or printed on the transparent conductive layer 2 of the transparent substrate 1. There is not especially a limit to either the application method or printing method for the dispersed liquid, the known method can be used. Specifically, with regard to the application method, for example, it is possible to use a dipping method, a spraying method, a wire bar method, a spin coating method, a roller coating method, a blade coating method, a gravure coating method or the like. In addition, with regard to the printing method, it is possible to use a relief printing method, an offset printing method, a gravure printing method, an intaglio printing method, a rubber printing method, a screen printing method or the like. It is noted that the order of the formation of the current-collecting wiring 3 and the protective layer 4, and the formation of the porous electrode 5 may be made the order different from the above order depending on the process conditions (such as the temperature, and pH in the chemical treatment) or the heat resistance and the chemical resistance of the materials.

For the purpose of electrically connecting the semiconductor fine particles to one another, increasing the mechanical strength of the porous electrode 5, and enhancing the adhesion between the transparent conductive layer 2 and the porous electrode 5 after the semiconductor fine particles have been either applied on or printed on the transparent conductive layer 2, the porous electrode 5 is preferably fired. Although there is not especially a limit to the range of the firing temperature, the firing temperature is normally, preferably set in the range of 400 to 700° C., and is more preferably set in the range of 400 to 650° C. because when the firing temperature is made to rise too much, the electrical resistance of the transparent conductive layer 2 is increased, and further the transparent conductive layer 2 may be melted. In addition, although there is not especially a limit to the firing time as well, normally, the firing time is set in the range of about ten minutes to about ten hours. In the phase of the firing, the current-collecting wiring 3 is also heated. However, since the current-collecting wiring 3 is made with the conductive paste containing therein the Ag particles and the low-melting point glass frit, the low-melting point glass frit flows and as a result, the flowing of the Ag particles is suppressed.

For the purpose of increasing the surface area of the semiconductor fine particles, and increasing the necking among the semiconductor fine particles after completion of the firing, for example, the porous electrode 5 may be subjected to a dipping treatment in either a liquid solution of titanium tetrachloride or a sol of titanium oxide superfine particles each having a particle diameter of 10 nm or less. When a plastic substrate is used as the transparent substrate 1 supporting the transparent conductive layer 2, the porous electrode 5 can be formed on the transparent conductive layer 2 by using a paste-like dispersed liquid solution containing therein a bonding material, and can also be pressure-bonded to the transparent conductive layer 2 by carrying out heating pressing.

Next, the transparent substrate 1 on which the porous electrode 5 is formed is dipped into the sensitizing dye liquid solution in which the photosensitizing dyes are dissolved in a predetermined solvent, thereby adsorbing the photosensitizing dyes on the porous electrode 5.

On the other hand, after the conductive layer 7 has been formed on the substrate 6 by utilizing the sputtering method or the like, the counter electrode 6 is formed on the conductive layer 7 by utilizing the sputtering method or the like.

Next, the transparent substrate 1 on which the porous electrode 5 is formed, and the counter electrode 8 are disposed in such a way that the porous electrode 5 and the counter electrode 8 face each other at a predetermined interval, for example, at an interval of 1 to 100 μm, preferably, at an interval of 1 to 50 μm. Also, the encapsulating material 9 is formed in an outer peripheral portion of each of the transparent substrate 1 and the counter electrode 8 to define a space within which the electrolyte layer is enclosed. Also, the electrolyte layer 10 is injected into the space through a liquid injection inlet (not shown) which, for example, is previously formed in the transparent substrate 1. After that, the liquid injection inlet is closed.

With that, the objective dye-sensitized photoelectric conversion element is manufactured.

### [Operation of Dye-Sensitized Photoelectric Conversion Element]

Next, an operation of the dye-sensitized photoelectric conversion element will be described in detail.

When the light is made incident to the dye-sensitized photoelectric conversion element, the dye-sensitized photoelectric conversion element operates as a cell with the counter electrode 8 and the transparent conductive layer 2 as a positive electrode and a negative electrode, respectively. The principles of the operation are as follows. Note that, in this case, it is supposed that an FTO is used as the material for the transparent conductive layer 2, TiO₂ is used as the material for the porous electrode 5, and redox species of I⁻/I₃⁻ are used as a redox couple. However, the present disclosure is by no means limited thereto.

When the photosensitized dye adsorbed on the porous electrode 5 absorbs a photon which is transmitted through both of the transparent substrate 1 and the transparent conductive layer 2 to be made incident to the porous electrode 5, an electron in the photosensitizing dye is excited from a ground state (LUMO: the Lowest Unoccupied Molecular Orbital) to an excited state (HOMO: the Highest Occupied Molecular Orbital). The electron thus excited is drawn to a conduction band of TiO₂ composing the porous electrode 5 through electrical coupling between the photosensitizing dye and the porous electrode 5 to pass through the porous electrode 5, thereby reaching the transparent conductive layer 2.

On the other hand, the photosensitizing dye from which the electron is lost receives an electron from a reducing agent, for example, I⁻ in the electrolyte layer 10 in accordance with the following reaction to generate an oxidizing agent, for example, I₃⁻ (a union of I₂ and I⁻) in the electrolyte layer 10:

2I⁻→I₂+2e⁻

I₂+I⁻→I₃⁻

The oxidizing agent thus generated reaches the counter electrode 8 due to the diffusion, and receives the electron from the counter electrode 8 in accordance with a reverse reaction of the reaction described above to be reduced to the original reducing agent.

I₃⁻→I₂+I⁻

I₂+2e⁻→2I⁻

After the electron sent from the transparent conductive layer 2 to an external circuit has made an electrical work in the external circuit, the electron returns back to the counter electrode 8. In such a way, the optical energy is converted into the electrical energy without leaving any of the changes in the electrolyte layer 10 as well as in the photosensitizing dye.

### EXAMPLES

A dye-sensitized photoelectric element was manufactured in the following manner.

A member in which an FTO layer was formed on a glass substrate was used as the transparent substrate 1 on which the transparent conductive layer 2 was formed.

After the conductive paste containing therein the Ag particles and the low-melting point glass frit had been applied onto the FTO layer so as to have a predetermined shape in which plural stripe electrodes branched off from a bus electrode, the conductive paste was solidified to form the current-collecting wiring 3 made with the Ag particles.

Next, after a TiO₂ film had been formed over the entire surface by utilizing the sputtering method, the TiO₂ film was patterned by carrying out etching to form the protective layer 4.

The paste-like dispersed liquid solution of TiO₂ as a raw material when the porous electrode 5 was formed was prepared by making reference to a Non-Patent Document of “The Newest Technology of Dye-Sensitized Solar Cell” (supervised by Hironori Arakawa, 2001, CMC Publishing Co., Ltd.). That is to say, firstly, 125 ml of titanium isopropoxide was gradually dropped to 0.1 M and 750 ml of a nitric acid liquid solution while 0.1 M and 750 ml of a nitric acid liquid solution was stirred at room temperature. After the dropping, the resulting liquid solution was moved to a constant-temperature bath set at 80° C., and the stirring was continuously carried out for eight hours, and as a result a white translucent sol liquid solution was obtained. After the resulting sol liquid solution had been open-cooled until room temperature was reached, and was filtered by using a glass filter, a solvent was added thereto, so that a volume of the liquid solution was set to 700 ml. After the resulting sol liquid solution had been moved to an autoclave and a hydrothermal reaction was then carried out at 220° C. for 12 hours, the resulting sol liquid solution was subjected to an ultrasonic treatment for one hour, thereby carrying out a dispersing treatment. Next, the resulting liquid solution was concentrated at 40° C. by using an evaporator, and was then prepared in such a way that a content of TiO₂ became 20 wt %. Polyethylene glycol (having a molecular weight of 500,000) for 20% of the mass of TiO₂, and anatase type TiO₂ having a particle diameter of 200 nm for 30% of the mass of TiO₂ were both added to the concentrated sol liquid solution, and were then uniformly mixed with one another in a stirring and defoaming device, thereby obtaining the paste-like dispersed liquid solution of TiO₂ having an increased viscosity.

The above paste-like dispersed liquid solution of TiO₂ was applied onto the FTO layer by utilizing the blade coating method, thereby forming a fine particle layer having a size of 5 mm×5 mm and a thickness of 200 μm. After that, the resulting fine particle layer of TiO₂ is held at 510° C. for 30 minutes to sinter the fine particles of TiO₂ on the FTO layer. 0.1 M of a titanium (IV) chloride TiCl₄ liquid solution had been dropped onto the TiO₂ film thus sintered, and was then held at room temperature for 15 hours, the cleaning was carried out and the firing was carried out at 500° C. for 30 minutes again. After that, an ultraviolet light was radiated to the TiO₂ sintered body for 30 minutes by using an ultraviolet radiating apparatus, whereby the impurities such as the organic substance contained in the TiO₂ sintered body were removed away through oxidative decomposition by a photocatalytic action of TiO₂, and a treatment for increasing the activity of the TiO₂ sintered body was carried out, thereby obtaining the porous electrode 5.

A member in which an FTO layer was formed on the glass substrate was used as the substrate 6 on which the conductive layer 7 was formed. The counter electrode 8 made of platinum was formed on the conductive layer 7 by utilizing the sputtering method.

23.8 mg of 2907 sufficiently purified as the photosensitizing dye was dissolved in 50 ml of a mixed solvent obtained by mixing acetonitrile and tert-butanol with each other at a volume ratio of 1:1, thereby preparing the photosensitizing dye liquid solution.

Next, the porous electrode 5 was dipped in the photosensitizing dye liquid solution prepared in the manner as described above at room temperature for 24 hours, and the photosensitizing dyes were held on the surfaces of TiO₂ fine particles. Next, after the porous electrode 5 had been cleaned by using an acetonitrile liquid solution of 4-tert-butylpyridine, and acetonitrile in order, the solvent was evaporated in a dark place to dry the porous electrode 5.

0.045 g of a sodium iodide (NaI), 1.11 g of 1-propyl-2,3-dimethylimidazolium iodide, 0.11 g of iodine (I₂), and 0.081 g of 4-tert-butylpyridine were dissolved in 3 g of methoxyacetonitrile, thereby preparing the electrolytic solution.

Next, the encapsulating material 9 was formed so as to surround the circumferences of the transparent substrate 11 and the substrate 6 in a state in which the transparent substrate 1 and the substrate 6 were made to face each other.

After that, the electrolytic solution was injected through the hole for solution injection which was previously provided in the transparent substrate 1, thereby forming the electrolyte layer 10.

With that, the objective dye-sensitized photoelectric conversion element was manufactured.

### <Evaluations of Conductive Paste>

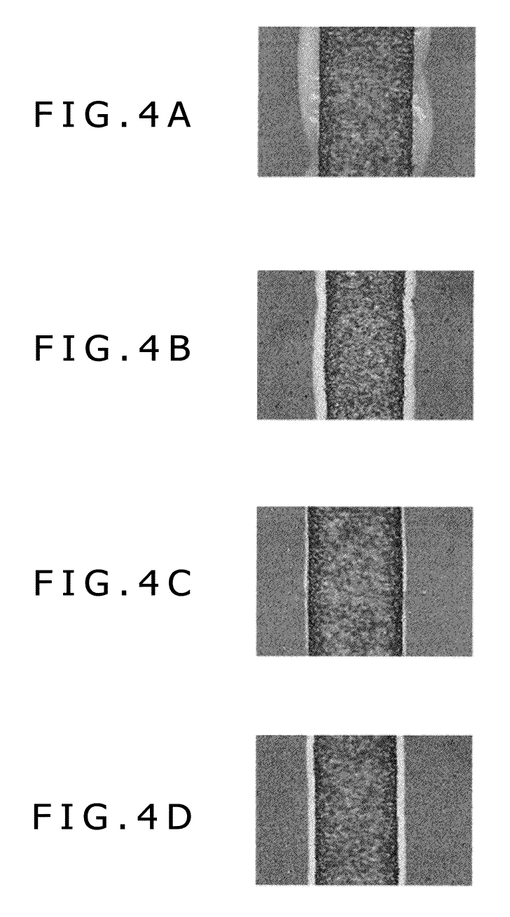

Basic evaluation experiments were carried out by changing the kind of low-melting point glass frit contained in the conductive paste used in formation of the current-collecting wiring 3. Four kinds of glass frits: a glass frit (glass frit A); a glass frit (glass frit B); a glass frit (glass frit C); and a glass frit (glass frit D) were used as the low-melting point glass frit. In this case, the glass frit (glass frit A) contains therein a bismuth oxide, a boron oxide, a zinc oxide, and an aluminum oxide, and a softening-point thereof is equal to or higher than 380° C. and equal to or lower than 400° C. The glass frit (glass frit B) contains therein a bismuth oxide, a zinc oxide, and a boron oxide, and a softening-point thereof is equal to or higher than 440° C. and equal to or lower than 460° C. The glass frit (glass frit C) contains therein a bismuth oxide, a boron oxide, a zinc oxide, a copper oxide, and a silicon oxide and a softening-point thereof is equal to or higher than 450° C. and equal to or lower than 470° C. Also, the glass frit (glass frit D) contains therein a bismuth oxide, a zinc oxide, a boron oxide, and a silicon oxide, and a silicon oxide and a softening-point thereof is equal to or higher than 460° C. and equal to or lower than 480° C. After the conductive paste containing therein both of the Ag particles and the low-melting point glass frit had been applied onto the FTO layer formed on the glass substrate in a stripe shape, and was then solidified, the porous electrode 5 made of the TiO₂ fine particles was formed and was then fired at 510° C. FIGS. 4A to 4D show light microscope photographs of specimens 1 to 4 using the glass frits A, B, C, and D, respectively, as the low-melting point glass frit. As shown in FIG. 4A, in the case of the specimen 1, the glass frit flowed to both sides of the current-collecting wiring made with the Ag particles over a width of 40 to 50 μm. Also, the Ag particles spread to the both sides of the current-collecting wiring at a width of about 250 μm in one side, the Ag particles precipitated were each small, and a height of the current-collecting wiring was reduced from 24 μm in the initial state to 21.5 μm. In the case of the specimen 2, the glass frit flowed to both sides of the current-collecting wiring made with the Ag particles over a width of 30 to 40 μm. Also, the Ag particles spread to the both sides of the current-collecting wiring at a width of about 300 μm in one side, the Ag particles precipitated were each moderately small, and a height of the current-collecting wiring was reduced from 20 μm in the initial state to 17 μm. In the case of the specimen 3, the glass frit flowed to both sides of the current-collecting wiring made with the Ag particles over a width of about 10 μm. Also, the Ag particles spread to the both sides of the current-collecting wiring at a width of about 500 μm in one side, the Ag particles precipitated were each large, and a height of the current-collecting wiring was reduced from 25 μm in the initial state to 23.5 μm. Also, in the case of the specimen 4, the glass frit flowed to both sides of the current-collecting wiring made with the Ag particles over a width of about 20 μm. Also, the Ag particles spread to the both sides of the current-collecting wiring at a width of about 350 μm in one side, the Ag particles precipitated were each large, and a height of the current-collecting wiring was reduced from 23.5 μm in the initial state to 21.5 μm. From these results, it is understood that there is a tendency in which as the softening point of the low-melting point becomes high, the flowing of the glass frit is reduced, the spreading of Ag is increased, and the Ag particles precipitated become each large. In any of the specimens 1 to 4, the flowing of the current-collecting wiring is sufficiently suppressed.

As has been described, according to the first embodiment of the present disclosure, since the current-collecting wiring 3 is made with the conductive paste containing therein the Ag particles and the low-melting point glass frit, the low-melting point glass frit flows in the phase of the firing of the porous electrode 5. As a result, it is possible to suppress the flowing of the Ag particles. For this reason, it is possible to suppress the flowing of the current-collecting wiring 3, it is possible to prevent the deterioration of the porous electrode 5 due to the content of Ag, and it is possible to enhance the long-term reliability of the dye-sensitized photoelectric element.

### 2. Second Embodiment

### Dye-Sensitized Photoelectric Conversion Element

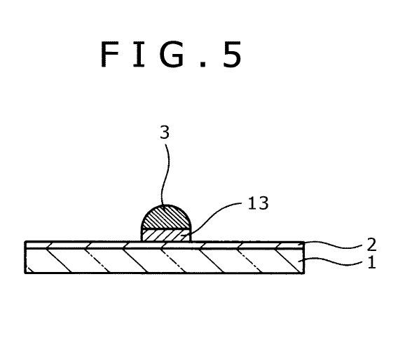

In a dye-sensitized photoelectric element according to a second embodiment of the present disclosure, as shown in FIG. 5, when the transparent conductive layer 2 made of an FTO is formed on the transparent substrate 1, the current-collecting wiring 3 made with the conductive paste containing therein the Ag particles and the low-melting point glass frit is formed on the transparent conductive layer 2 through a conductive adhesion layer 13. That is to say, the conductive adhesion layer 13 is formed on the transparent conductive layer 2 made of the FTO, and the current-collecting wiring 3 is then formed on the conductive adhesion layer 13. The conductive adhesion layer 13, for example, is made of at least one kind of metal selected from the group consisting of Ag, Au, Pt, Ti, Cr, Al, and Cu.

The structure of the dye-sensitizing photoelectric conversion element other than the structure described above is the same as that of the dye-sensitizing photoelectric conversion element according to the first embodiment of the present disclosure.

### [Method of Manufacturing Dye-Sensitizing Photoelectric Conversion Element]

A method of manufacturing the dye-sensitizing photoelectric conversion element according to the second embodiment of the present disclosure is the same as that of manufacturing the dye-sensitizing photoelectric conversion element of the first embodiment except that the current-collecting wiring 3 is formed on the transparent conductive layer 2 through the conductive adhesion layer 13.

According to the second embodiment of the present disclosure, it is possible to obtain effects which will be described below. That is to say, in the case where the current-collecting wiring 3 made with the conductive paste containing therein the Ag particles and the low-melting point glass frit is formed on the transparent conductive layer 2 made of the FTO, when the current-collecting wiring 3 is formed through the conductive adhesion layer 13, the contact resistance can be reduced as compared with the case where the current-collecting wiring 3 is directly formed on the transparent conductive layer 2. The reason for this is because the adhesiveness of the Ag particles for the conductive adhesion layer 13 is more excellent than that of the Ag particles contained in the conductive paste for the transparent conductive layer 2 made of the FTO. As has been described, it is possible to reduce the contact resistance of the current-collecting wiring 3 for the transparent conductive layer 2, whereby it is possible to obtain the excellent power-collecting performance, and it is in turn possible to enhance the photoelectric conversion efficiency of the dye-sensitized photoelectric conversion element.

### 3. Third Embodiment

### Dye-Sensitized Photoelectric Conversion Element

In a dye-sensitized photoelectric conversion element according to a third embodiment of the present disclosure, a description will be given below with respect to optimization of a pattern shape of the current-collecting wiring 3.

In the dye-sensitized photoelectric conversion element, as shown in FIG. 2A or 2B, the current-collecting wiring 3 is composed of the bus electrode 3a having the relatively wide pattern, and the finger electrodes 3b branching off from the bus electrode 3a and each having the relatively fine pattern. The bus electrode 3a either may be provided on the porous electrode 5 or may be provided on a portion other than the porous electrode 5.

Since the finger electrodes 3b are formed on a light incidence surface side of the dye-sensitized photoelectric conversion element, when the area of the finger electrodes 3b is made large, an effective light receiving area is reduced and an electric-generating capacity of the dye-sensitized photoelectric conversion element is reduced accordingly. Contrary to this, when each of the finger electrodes 3b is made fine to reduce the area of the finger electrodes 3b, a power-collecting resistance of each of the finger electrodes 3b is increased and the resistance loss is increased accordingly.

In addition, since the finger electrode 3b power-collects the current generated through the power generation in the porous electrode 5 from a terminal thereof to a base thereof, the current which is caused to flow from the terminal toward the base per unit length of the finger electrode 3b is increased. When it is assumed that a current i₀ (A/m²) is uniformly generated on the surface of the porous electrode 5, the current I₀ is expressed by Expression (1):

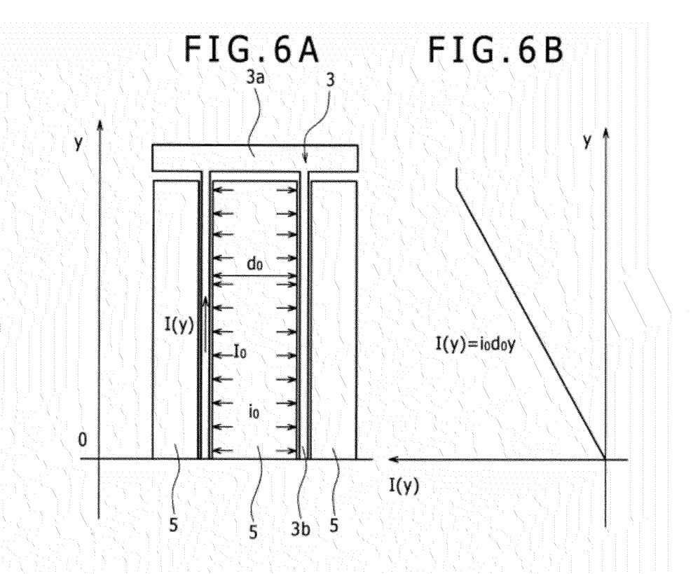

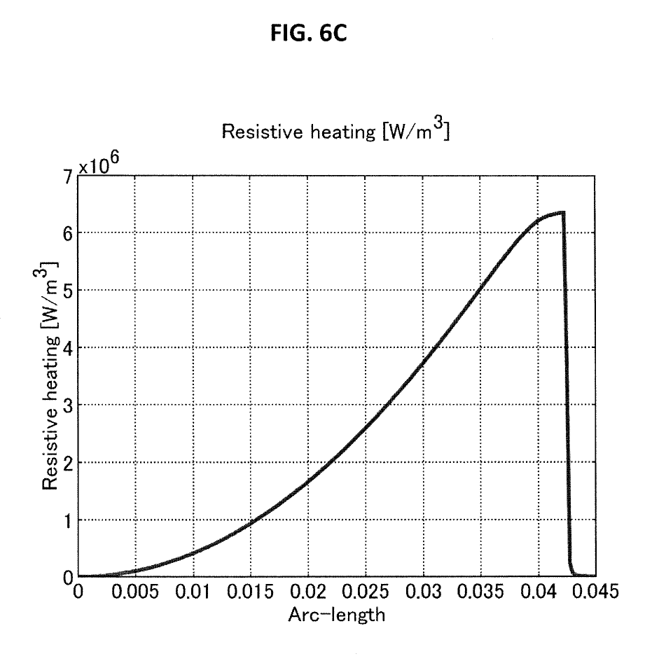

I₀=i₀×d₀ (1)

where I₀ is a current (A/m) caused flow into a unit length of the finger electrode 3b, and d₀ is a width (m) of the porous electrode 5 (an interval of the finger electrodes 3b). For this reason, as shown in FIGS. 6A and 6B, a current I(y) caused to flow through a portion, y, from the terminal of the finger electrode 3b is expressed by Expression (2):

I(y)=I₀×y=i₀d₀y (2)

Thus, the current I(y) is increased in proportion to y.

At this time, a loss density q(y) (W/m²) on the finger electrode 3b in the portion, y, is expressed by Expression (3):

q(y)=RI(y)²/t=ρ₀I₀²y²/h₀t²=ρ₀(d₀i₀y)²/h₀t² (3)

where ρ₀ is a volume resistance (Ωm) of the material composing the finger electrode 3b, h₀ is a height (m) of the finger electrode 3b, and t is a width (m) of the finger electrode 3b. Thus, the loss density q(y) is increased in proportion to a square of y (refer to FIG. 6C).

The height, h₀, of the finger electrode 3b may not be necessarily constant. However, preferably, the constant height, h₀, results in that the manufacture is easy from the reason of the process such as the screen printing, the dispensing, and the like of the conductive paste, and the quality control also comes easy.

Here, when the finger electrode 3b is gradually widened from the terminal toward a portion merged with the bus electrode 3a, and a change in the width of the finger electrode 3b is expressed by Expression (4), it is possible to optimize a balance between the effective area of the porous electrode 5, and the area of the finger electrode 3b. As a result, it is possible to maximize the output from the dye-sensitized photoelectric conversion element.

In the environment in the phase of the rated power generation,

(1) a calorific value per unit area on the finger electrode 3b becomes approximately equal to the electric-generating capacity per unit area of the porous electrode 5.

(2) Specifically, a width t (m) of the finger electrode 3b is made to fulfill Expression (4):

$$t = {d}_{0} {i}_{0} y \times \sqrt{\frac{{ρ}_{0}}{{h}_{0} {W}_{0}}} \qquad ( 4 )$$

where d₀ is a power generation electrode width (an interval of the finger electrodes 3b) (m), i₀ is a rated power generation current density (A/m²), y is a distance (m) from the terminal of the finger electrode 3b, ρ₀ is volume resistivity (Ωm) of a material of the finger electrode 3b, h₀ is a thickness (m) of the finger electrode 3b, and W₀ is a generated power output density (W/m²).

(3) The width of the finger electrode 3b falls within the range of −70 to +100% of the width value expressed by Expression (4).

Expression (4) can be derived in the manner which will be described below. Let W₀ (W/m²) be the generated power output density on the porous electrode 5, and let q(y) (W/m²) be the calorific value (loss) per unit area in the position which is located at the distance, y, from the terminal on the finger electrode 3b (refer to Expression (3)). When the width of the position, y, is increased by Δt, the reduction in the generated power output on the porous electrode 5 is expressed by following expression:

ΔW=−WΔt

In addition, the reduction in the loss in the position, y, on the finger electrode 3b is expressed by Expression (5):

$$Δ Q ( y ) = \frac{{ρ}_{0} {I}_{0}^{2} {y}^{2}}{{h}_{0} t} - \frac{{ρ}_{0} {I}_{0}^{2} {y}^{2}}{{h}_{0} ( t + Δ t )} = \frac{{ρ}_{0} {I}_{0}^{2} {y}^{2} Δ t}{{h}_{0} t ( t + Δ t )} \qquad ( 5 )$$

Here, when a denominator of Expression (5) is mathematically removed, and a second-order term of Δt is ignored, Expression (5) is transformed into Expression (6):

$$Δ Q ( y ) = \frac{{ρ}_{0} {I}_{0}^{2} {y}^{2} Δ t}{{h}_{0} {t}^{2}} \qquad ( 6 )$$

For the purpose of obtaining a balance between the reduction in the generated power output on the porous electrode 5, and the reduction in the loss on the finger electrode 3b, thereby obtaining the maximum output, (ΔQ+ΔW) is maximized:

$$\begin{matrix}Δ Q + Δ W = ( \frac{{ρ}_{0} {I}_{0}^{2} {y}^{2}}{{h}_{0} {t}^{2}} - {W}_{0} ) Δ t & ( 7 ) \\ \frac{Δ ( Q + W )}{Δ t} = \frac{{ρ}_{0} {I}_{0}^{2} {y}^{2}}{{h}_{0} {t}^{2}} - {W}_{0} & ( 8 )\end{matrix}$$

When a right side of Expression (8) is put to zero and Expression (8) is solved with respect to t, Expression (4) is derived.

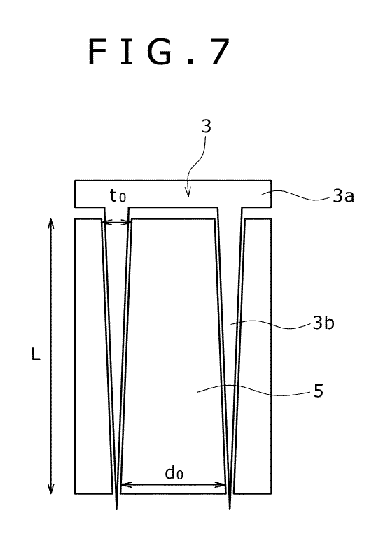

That is to say, the width, t, of the finger electrode 3b is changed depending on the distance, y, from the terminal of the finger electrode 3b in accordance with Expression (4), thereby making it possible to maximize (ΔQ+ΔW). FIG. 7 shows an ideal shape of the finger electrode 3b whose width, t, is changed in accordance with Expression (4).

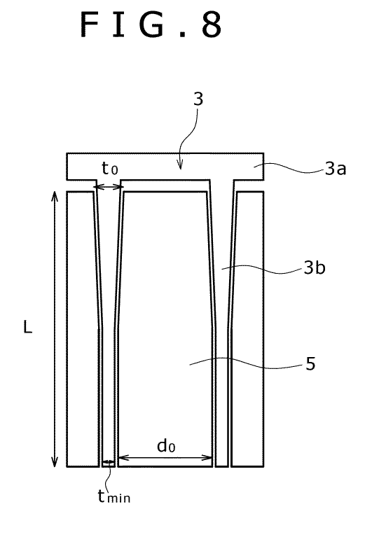

However, it may be impossible to make the width of the terminal of the finger electrode 3b close to zero from the reason of the process such as the screen printing, the dispensing, and the like. Then, when let tₘᵢₙ be a minimum width of the finger electrode 3b determined depending on the process, in this case, it is preferable to form a shape as shown in FIG. 8.

A material having a large electrical conductivity is preferable for the material for the finger electrode 3b, and a metallic material such as Ag, Pt, Ru, Au, Cu, Ni, Mo or Ti is preferable. In addition, since an iodine system electrolytic solution is used in the dye-sensitized photoelectric conversion element in many cases, a material having a higher corrosion resistance against the electrolytic solution is preferably for the material for the finger electrode 3b.

The loss reduction when the pattern shape of the current-collecting wiring 3 described above was optimized was evaluated from wiring simulations.

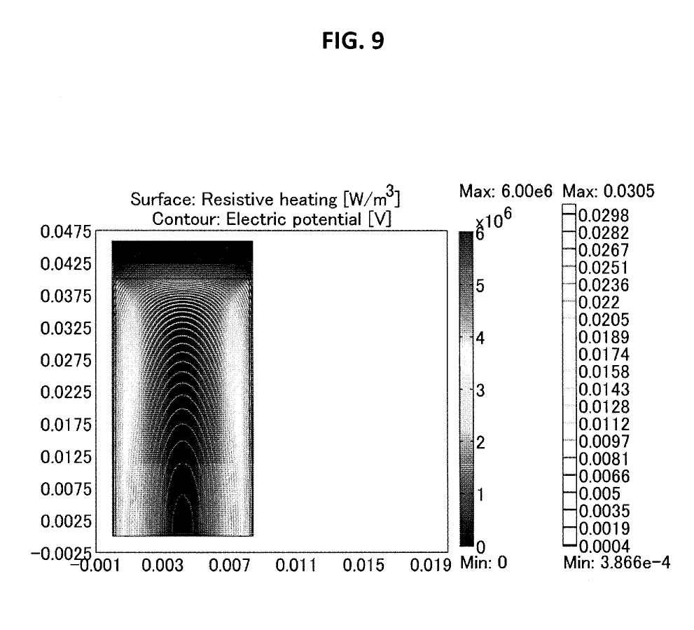

FIG. 9 shows a result of the simulation before application of this optimization. As can be seen from FIG. 9, a loss per module when the width of the porous electrode is 8 mm is 6.13 mW.

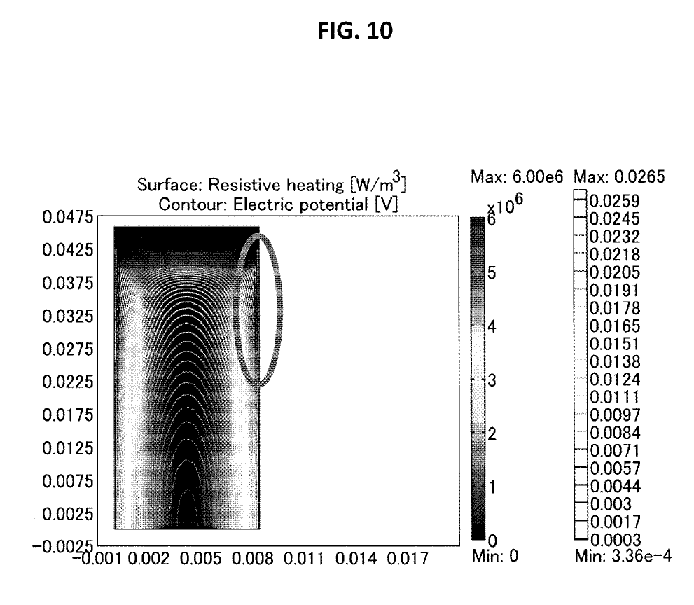

FIG. 10 shows a result of the simulation after application of this optimization. A loss per module when the width of the porous electrode 5 is 8 mm is 5.06 mW. From this, it is understood that the loss per module in this case is reduced by approximately about 1 mW as compared with the case before application of this optimization. It is understood that a portion surrounded by a circle indicated in FIG. 10 is changed from that shown in FIG. 9, and thus the loss is reduced.

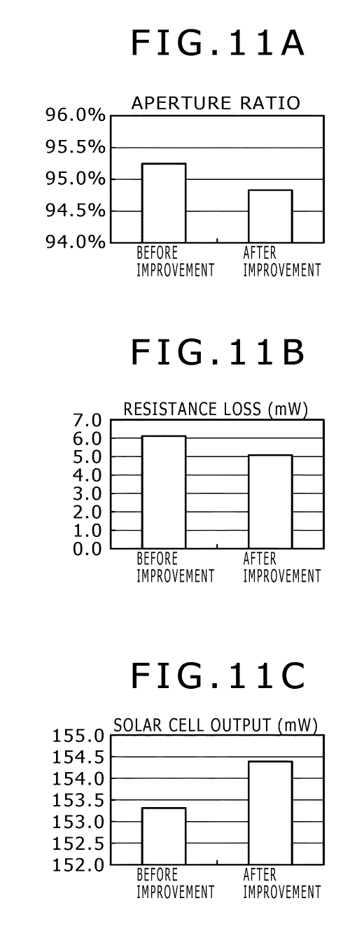

FIGS. 11A, 11B, and 11C show results of obtaining an aperture ratio, a resistance loss, and a final output of the dye-sensitized photoelectric conversion element from simulations, respectively. As can be seen from FIGS. 10A, 10B, and 10C, although the aperture ratio is slightly reduced due to this optimization, the effect of the reduction of the resistance loss is superior to the slight reduction in the aperture ratio, and thus the final output from the dye-sensitized photoelectric conversion element is improved by about 1.1 mW.

According to the third embodiment of the present disclosure, in addition to the same effects as those in the first embodiment, the following effects can be obtained. That is to say, the current-collecting wiring 3 is formed so as to be composed of the bus electrode 3a and the finger electrodes 3b, and the width, t, of each of the finger electrodes 3b is changed in accordance with Expression (4). Therefore, it is possible to maximize the output from the dye-sensitized photoelectric conversion element. In addition, the width, t, of each of the finger electrodes 3b starts with the smallest width in the process in the terminal of each of the finger electrodes 3b, and the width, t, in the middle is increased in accordance with Expression (4), whereby it is possible to maximize the output from the dye-sensitized photoelectric conversion element while it is adapted to the manufacture process. In addition, since the material of each of the finger electrodes 3b is the metallic material such as Ag, Pt, Ru, Au, Cu, Ni, Mo or Ti, the electric power can be efficiently collected with the finger electrodes 3b, and thus it is possible to maximize the output from the dye-sensitized photoelectric conversion element.

### 4. Fourth Embodiment

### Dye-Sensitized Photoelectric Conversion Element

In a dye-sensitized photoelectric conversion element according to a fourth embodiment of the present disclosure, a description will now be given with respect to optimization of a pattern shape of the current-collecting wiring 3 by utilizing a method different from that in the third embodiment.

In the dye-sensitized photoelectric conversion element, as shown in FIG. 3B, the current-collecting wiring 3 is composed of the bus electrode 3a having the wide pattern, and the stripe electrode 3d branching off from the bus electrode 3a and each having the fine pattern.

A pitch (line cycle) of the stripe electrodes 3d is selected so as to fulfill the following expression:

$${d}_{0} = \sqrt{\frac{3 t {W}_{0}}{{R}_{0} {i}_{0}^{2} {l}^{2}} + {t}^{2}}$$

where t is a width (m) of the stripe electrode 3d, W₀ is a rated generated power output density (W/m²), R₀ is a line resistance (Ω/m) of the stripe electrode 3d, i₀ is a rated generated power current density (A/m²), and 1 is a power-collecting distance (m) of the stripe electrode 3d.

Or, the pitch of the stripe electrodes 3d is selected so as to fall within the range of −70% to +250% of the pitch calculated from the above expression from the reason of the convenience in the process, the external appearance, the manufacture error, and the like. That range corresponds to the range in which the output from the dye-sensitized photoelectric conversion element is reduced by −30% from the optimal point.

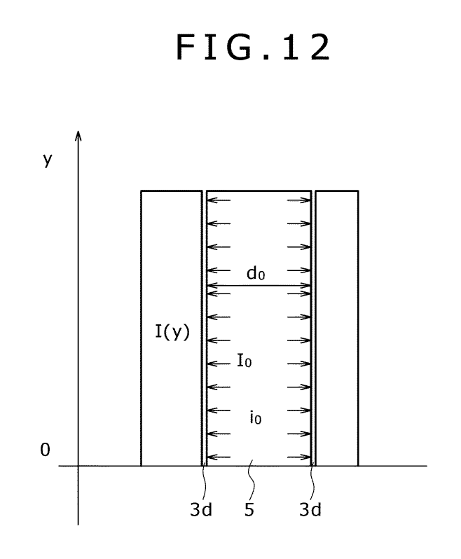

The above expression (13) can be derived in the manner which will be described below. Firstly, a resistance loss per unit area on the stripe electrode 3d is calculated. When it is assumed that a current i₀ (A/m²) is uniformly generated on the surface of the porous electrode 5, the current I₀ is expressed by following expression (refer to FIG. 12):

I₀=i₀×(d₀−t)

wherein I₀ is a current (A/m) caused to flow through a unit length of the stripe electrode 3d, t is the width (m) of the stripe electrode 3d, d₀ is a pitch of the stripe electrodes 3d, and R is a line resistance (Ω/m) of the stripe electrode 3d. The resistance loss q(y) (W/m²) per unit area in the position which is located at a distance, y, from the terminal of the stripe electrode 3d is expressed by following expression:

$$q ( y ) [ W \text{/} {m}^{2} ] = \frac{{RI ( y )}^{2}}{t ( y )} = \frac{{R ( {\int }_{0}^{y} i ( y ) d y )}^{2}}{t} = \frac{{R ( {\int }_{0}^{y} {i}_{0} ( {d}_{0} - t ) d y )}^{2}}{t}$$

When the above expression is integrated with t as a constant, the resistance loss q(y) (W/m²) per unit area is expressed by following expression:

$$q ( y ) = \frac{{ρ}_{0} {i}_{0}^{2} {y}^{2}}{{h}_{0} {t}_{0}^{2}} {( {d}_{0} - {t}_{0} )}^{2}$$

where ρ₀ is a volume resistance (Ωm) of a metal, and has the following relationship with R expressed by following expression:

$$R ( y ) [ Ω \text{/} m ] = \frac{{ρ}_{0}}{{h}_{0} t}$$

Next, when the above expression is integrated with respect to a direction of a length of the stripe electrode 3d, following expression can be obtained, and thus it is possible to calculate the resistance loss Q (W/m) per unit width of the stripe electrode 3d.

$$\begin{matrix}Q [ W \text{/} m ] = {\int }_{0}^{l} \frac{{ρ}_{0} {i}_{0}^{2} {y}^{2}}{{h}_{0} {t}_{0}^{2}} {( {d}_{0} - {t}_{0} )}^{2} d y \\ = \frac{{ρ}_{0} {i}_{0}^{2} {l}^{3}}{3 {h}_{0} {t}_{0}^{2}} {( {d}_{0 } - {t}_{0} )}^{2} \\ = \frac{{R}_{0} {i}_{0}^{2} {l}^{3}}{3 {t}_{0}} {( {d}_{0} - {t}_{0} )}^{2}\end{matrix}$$

When the above expression is multiplied with the width, t₀, of the stripe electrode 3d, the resistance loss per one stripe electrode 3d can be calculated from following expression:

$$Q [ W ] = \frac{{R}_{0} {i}_{0}^{2} {l}^{3}}{3} {( {d}_{0} - {t}_{0} )}^{2}$$

Next, for the purpose of searching for a maximum value of {W (generated power)−Q (power-collecting loss)} for the width, t, of the stripe electrode 3d, a distance between {W (generated power)−Q (power-collecting loss)} for a minimal change of t is calculated. An increase in t results in that W is decreased because the aperture ratio is reduced, and Q is also decreased because the resistance of the current-collecting wiring is reduced.

$$\begin{matrix}\begin{matrix}Δ Q [ W ] = \frac{{ρ}_{0} {i}_{0}^{2} {l}^{3}}{3 {h}_{0}} [ \frac{{( {d}_{0} - t )}^{2}}{t} - \frac{{( {d}_{0} - t - Δ t )}^{2}}{t + Δ t} ] \\ = \frac{{ρ}_{0} {i}_{0}^{2} {l}^{3}}{3 {h}_{0} t ( t + Δ t )} [ ( t + Δ t ) {( {d}_{0 } - t )}^{2} - {t ( {d}_{0} - t - Δ t )}^{2} ] \\ = \frac{{ρ}_{0} {i}_{0}^{2} {l}^{3}}{3 {h}_{0} t ( t + Δ t )} [ \begin{matrix}( t + Δ t ) {( {d}_{0 } - t )}^{2} - \\ t \{ {( {d}_{0} - t )}^{2} - 2 Δ t ( {d}_{0} - t ) + Δ {t}^{2} \}\end{matrix} ] \\ = \frac{{ρ}_{0} {i}_{0}^{2} {l}^{3}}{3 {h}_{0} t ( t + Δ t )} [ Δ {t ( {d}_{0 } - t )}^{2} + 2 t Δ t ( {d}_{0} - t ) ] \\ = \frac{{ρ}_{0} {i}_{0}^{2} {l}^{3}}{3 {h}_{0} t ( t + Δ t )} Δ t ( {d}_{0}^{2} - {t}^{2} ) \\ = \frac{{ρ}_{0} {i}_{0}^{2} {l}^{3}}{3 {h}_{0} t ( t + Δ t ) ( t - Δ t )} Δ t ( {d}_{0}^{2} - {t}^{2} ) ( t - Δ t ) \\ = \frac{{ρ}_{0} {i}_{0}^{2} {l}^{3}}{3 {h}_{0} {t}^{2}} Δ t ( {d}_{0}^{2} - {t}^{2} )\end{matrix} \\ Δ W [ W ] = {W}_{0} l Δ t \\ \frac{Δ Q + Δ W}{Δ t} = \frac{{ρ}_{0} {i}_{0}^{2} {l}^{3}}{3 {h}_{0} {t}^{2}} ( {d}_{0}^{2} - {t}^{2} ) - {W}_{0} l = 0\end{matrix}$$

From expressions described above, a point (local maximum point) at which a differential, (ΔW+ΔQ)/Δt, becomes zero is obtained in accordance with following expressions:

$$\frac{{R}_{0} {i}_{0}^{2} {l}^{3}}{3 t} ( {d}_{0}^{2} - {t}^{2} ) - {W}_{0} l = 0$$

$${d}_{0}^{2} = \frac{3 t {W}_{0}}{{R}_{0} {i}_{0}^{2} {l}^{2}} + {t}^{2}$$

By solving expression described above with respect to d₀, following expression is obtained:

$${d}_{0} = \sqrt{\frac{3 t {W}_{0}}{{R}_{0} {i}_{0}^{2} {l}^{2}} + {t}^{2}}$$

That is to say, d₀ expressed by the above expression becomes the pitch of the stripe electrodes 3d giving the output local maximum point.

A material having a large electrical conductivity is preferable for the material for the current-collecting wiring 3, and a metallic material such as Ag, Pt, Ru, Au, Cu, Ni, Mo or Ti is preferable. In addition, since an iodine system electrolytic solution is used in the dye-sensitized photoelectric conversion element in many cases, a material having a higher corrosion resistance against the electrolytic solution is preferably for the material for the finger electrode 3b.

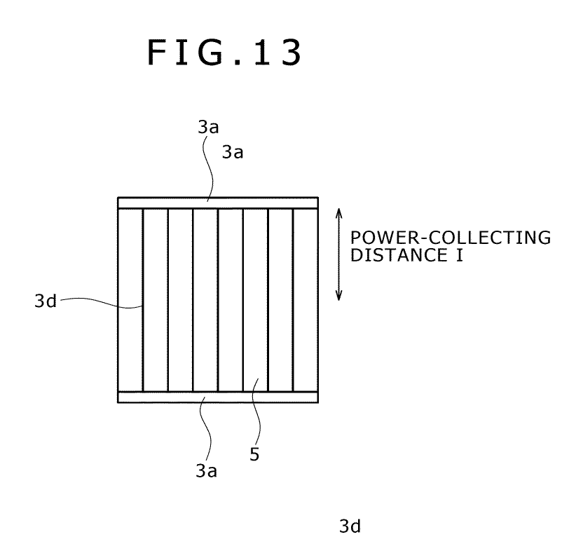

As shown in FIG. 13, the bus electrodes 3a are provided along two sides facing each other of the transparent substrate 1. In the case of the structure in which the electric power is collected in these bus electrodes 3a, a power-collecting distance 1 becomes half a power-collecting distance when the electric power is collected only in one of the two bus electrodes 3a.

Actual calculation examples will now be described. However, in this case, there is calculated the optimal pitch of the stripe electrodes 3d when a silver alloy (conductivity: 3.33×10⁷ S/m), molybdenum (Mo) (conductivity: 6.25×10⁶ S/m) or ruthenium (Ru) (conductivity: 7.14×10⁶ S/m) is used as the material for the current-collecting wiring 3. It is supposed that the height of the stripe electrode 3d is 1 μm, the width thereof is 50 μm, and the power-collecting length (module length) is 0.3 m. The rated area current density is 10 A/m², and the rated generated power output density is 5 W/m². TABLE 1 shows the calculation results. From TABLE 1, it is understood that in the silver alloy having the larger conductivity, the electrode pitch is 376 μm, that is the aperture ratio is large and optimum, whereas in each of Mo and Ru, each having the smaller conductivity, the optimal electrode pitch becomes narrow and the aperture ratio is also small.

TABLE 1

| | conductivity | optimal electrode | aperture |
|---|---|---|---|
| | (S/m) | pitch (μm) | ratio |
| silver alloy | 3.33 × 10⁷ | 376 | 86.7% |
| Mo | 6.25 × 10⁶ | 169 | 70.4% |
| Ru | 7.14 × 10⁶ | 180 | 72.2% |

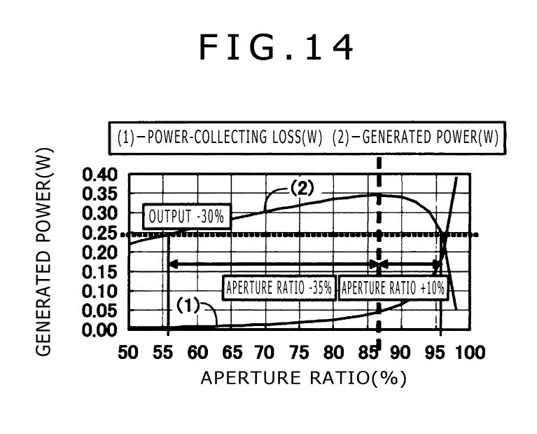

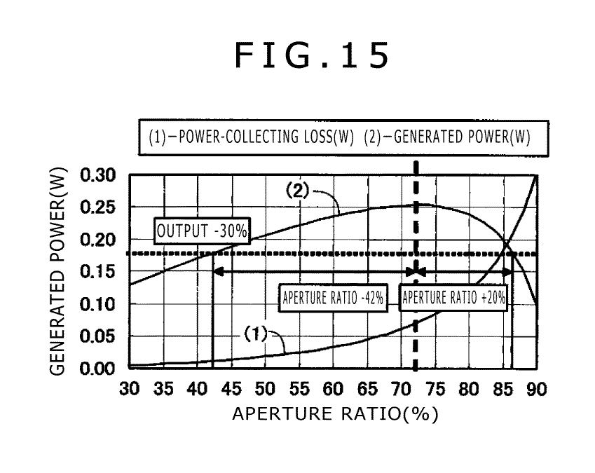

FIG. 14 shows calculation results of the output from the dye-sensitized photoelectric conversion element module in which the pitch of the stripe electrodes 3d is made variable with respect to the case where the silver alloy is used as the material for the current-collecting wiring 3 under the calculation condition described above. As shown in FIG. 14, the generated power output becomes maximum at the aperture ratio of 86.7% as the calculation result shown in TABLE 1. In addition, the range in which the output of 70% of the maximum output point is obtained falls within the range in which the aperture ratio shows −35% to +10% with respect to the optimal point. This range corresponds to the range of −70 to +230% in terms of the pitch of the stripe electrode 3d.

Likewise, FIG. 15 shows calculation results of the output from the dye-sensitized photoelectric conversion element module in which the pitch of the stripe electrode 3d is made variable with respect to the case where Ru is used as the material for the current-collecting wiring 3 under the calculation condition described above. The generated power output becomes maximum at the aperture ratio of 72.2% as the calculation result shown in TABLE 1. In addition, the range in which the output of 70% of the maximum output point is obtained falls within the range in which the aperture ratio shows −42% to +20% with respect to the optimal point. This range corresponds to the range of −50 to +100% in terms of the pitch of the stripe electrodes 3d.

According to the fourth embodiment of the present disclosure, it is possible to obtain the same advantages as those in the third embodiment. In particular, the pitch of the stripe electrodes 3d is set in the range of −70 to +250% of the pitch obtained from the calculation, whereby it is possible to obtain the output of 70% or more of the optimal point with respect to the output from the dye-sensitized photoelectric conversion element.

### 5. Fifth Embodiment

### Dye-Sensitized Photoelectric Conversion Element

In a dye-sensitized photoelectric conversion element according to a fifth embodiment of the present disclosure, a description will now be given with respect to optimization of a pattern shape of the current-collecting wiring 3 by utilizing a method different from that in each of the third and fourth embodiments.

In the dye-sensitized photoelectric conversion element, as shown in FIG. 3A, the current-collecting wiring 3 is composed of the bus electrode 3a having the wide pattern, and the grid electrode 3c electrically connected to the bus electrode 3a.

In the grid electrode 3c, it is preferable to combine the results of calculations of the stripe electrodes 3d in the fourth embodiment with the aperture ratio. That is to say, the optimal aperture ratio, Ap, which is obtained from the line resistance, the width, the rated generated power output, and the rated generated power current density of the stripe electrode composing the grid electrode 3c is selected in accordance with following expression. Here, the aperture ratio is a value obtained by dividing the area, of the portion not covered with the grid electrode 3c, of the area of the porous electrode 5 by the entire area of the porous electrode 5.

$$Ap = \frac{1}{\sqrt{\frac{3 t {W}_{0}}{{R}_{0} {i}_{0}^{2} {l}^{2} {t}^{2}} + 1}}$$

The aperture ratio of the grid electrode 3c may fall within the range of −40 to +20% of the aperture ratio calculated from the above expression from the reasons of the convenience of the process, the external appearance, the manufacture error, and the like. That range corresponds to the range in which the output from the dye-sensitized photoelectric conversion element is reduced by −30% from the optimal point.

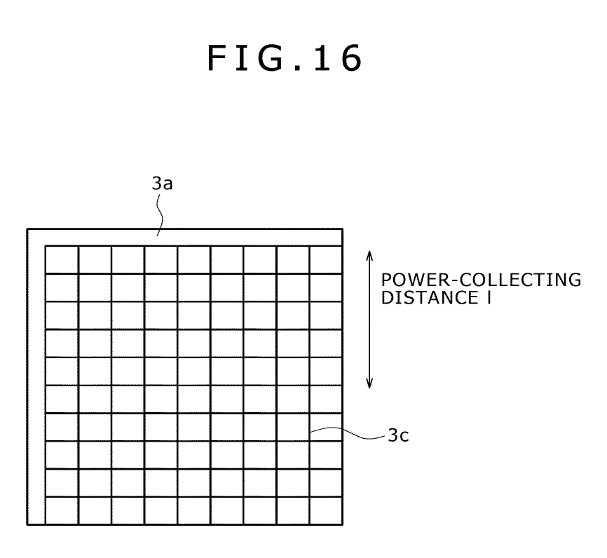

In addition, as shown in FIG. 16, in the case of a structure in which the electric power is collected with the bus electrodes 3a provided along two sides perpendicular to each other of the transparent substrate 1 the power-collecting distance 1 becomes half a power-collecting distance when the electric power is collected with the bus electrode 3a provided along only one side.

According to the fifth embodiment of the present disclosure, it is possible to obtain the same advantages as those in the third embodiment. In particular, the aperture ratio when the mesh electrode 3c is used is set in the range of −40 to +20% of the aperture ratio obtained from the calculation, whereby it is possible to obtain the output of 70% or more of the optimal point with respect to the output from the dye-sensitized photoelectric conversion element.

### 6. Sixth Embodiment

### Dye-Sensitized Photoelectric Conversion Element

In a dye-sensitized photoelectric conversion element according to a six embodiment of the present disclosure, the porous electrode 5 is composed of a metal/metal oxide fine particles, typically, is composed of a sintered body obtained by sintering the metal/metal oxide fine particles.

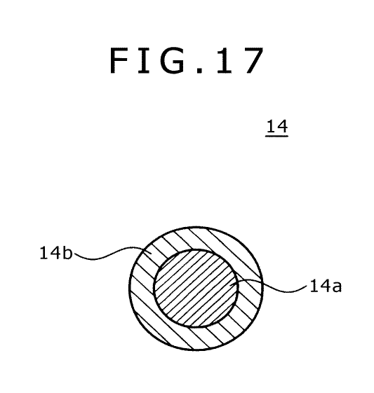

FIG. 17 shows details of a structure of the metal/metal oxide fine particle. As shown in FIG. 17, the metal/metal oxide fine particle 14 has a core/shell structure composed of a spherical core 14a made of the metal, and a shell 14b made of the metal oxide surrounding the circumference of the spherical core 14a. In the metal/metal oxide fine particle 14, one or plural kinds of photosensitizing dyes are coupled to (or adsorbed on) the surface of the shell 14b made of the metal oxide.

For example, a titanium oxide (TiO₂), a tin oxide (SnO₂), a niobium oxide (Nb₂O₅), a zinc oxide (ZnO) or the like is used as the metal oxide composing the shell 14b of the metal/metal oxide fine particles 14. Of these metal oxides, TiO₂, especially, the anatase type TiO₂ is preferably used. However, the kinds of metal oxides are by no means limited thereto, and thus two or more kinds of metal oxides can be used through either the mixing or the composition to be used as may be necessary. In addition, the shape of the metal/metal oxide fine particle 14 may be any of a particle-like shape, a tube-like shape, a rod-like shape or the like.

Although there is not especially a limit to the particle size of the metal/metal oxide fine particles 14, in general, the particle size is in the range of 1 to 500 nm in an average particle size of the primary particle, especially, preferably, in the range of 1 to 200 nm, and is especially, more preferably in the range of 5 to 100 nm. In addition, the particle size of the core 14a of the metal/metal oxide fine particles 14 is generally in the range of 1 to 200 nm.

Others are the same as those in the first embodiment.

### [Method of Manufacturing Dye-Sensitized Photoelectric Conversion Element]

Next, a description will be given concretely with respect to a method of manufacturing the dye-sensitized photoelectric conversion element.

Firstly, the transparent conductive layer 2 is formed on one principal surface of the transparent substrate 1 by utilizing the sputtering method, and the current-collecting wiring 3 is formed on the transparent conductive layer 2.

Next, the porous electrode 5 composed of the metal/metal oxide fine particles 14 is formed on the transparent conductive layer 2.

For the purpose of electrically connecting the metal/metal oxide fine particles 14 to one another, increasing the mechanical strength of the porous electrode 5, and enhancing the adhesiveness between the transparent conductive layer 2 and the metal/metal oxide fine particles 14 after the metal/metal oxide fine particles 14 have been either applied on or printed on the transparent conductive layer 2, the porous electrode 5 is preferably fired.

After that, the process is made to proceed similarly to the case of the first embodiment, and the objective dye-sensitized photoelectric conversion element is manufactured.

The metal/metal oxide fine particles 14 composing the porous electrode 5 can be manufactured by utilizing the existing known method. This method, for example, is described in a Non-Patent Document of Jpn. J. Appl. Phys., Vol. 46, No. 4B, 2007, pp. 2567-2570. An outline of a method for manufacturing the metal/metal oxide fine particle 14 in which the core 14a is made of Au, and the shell 14b is made of TiO₂ will be described as an example as follows. That is to say, firstly, a heated liquid solution of 5×10⁻⁴ M and 500 ml of HAuCl₄ is mixed with a dehydro citric acid 3 natrium while the stirring is carried out. Next, after 2.5 wt % of mercaptoundecanoic acid has been added to an ammonia liquid solution while the stirring is carried out, the resulting liquid solution is added to the Au nano-particle dispersed liquid solution and the heat is kept for two hours. Next, 1 M of HCl is added to the resulting liquid solution, so that pH of the liquid solution is adjusted to 3. Next, both of titanium isopropoxide and triethanolamine are added to an Au colloid liquid solution at the nitrogen ambient atmosphere. In such a way, the metal/metal oxide fine particles 14 are manufactured in each of which the core 14a is made of Au and the shell 14b is made of TiO₂.

### [Operation of Dye-Sensitized Photoelectric Conversion Element]

Next, an operation of the dye-sensitized photoelectric conversion element will be described in detail.

When the light is made incident to the dye-sensitized photoelectric conversion element, the dye-sensitized photoelectric conversion element operates as a cell with the counter electrode 8 and the transparent conductive layer 2 as a positive electrode and a negative electrode, respectively. The principles of the operation are as follows. Note that, in this case, it is supposed that an FTO is used as the material for the transparent conductive layer 2, Au is used as the material for the core 14a of the metal/metal oxide fine particles 14 composing the porous electrode 5, TiO₂ is used as the material for the shell 14b, and redox species of I⁻/I₃⁻ are used as a redox couple. However, the present disclosure is by no means limited thereto.

When the photosensitized dye coupled to the porous electrode 5 absorbs a photon which is transmitted through both of the transparent substrate 1 and the transparent conductive layer 2 to be made incident to the porous electrode 5, an electron in the photosensitizing dye is excited from a ground state (LUMO: the Lowest Unoccupied Molecular Orbital) to an excited state (HOMO: the Highest Occupied Molecular Orbital). The electron thus excited is drawn to a conduction band of TiO₂ composing the shell 14b of the metal/metal oxide fine particles 14 composing the porous electrode 5 through electrical coupling between the photosensitizing dye and the porous electrode 5 to pass through the porous electrode 5, thereby reaching the transparent conductive layer 2. In addition thereto, the light is made incident to the surface of the core 14a made of Au of the metal/metal oxide fine particles 14, whereby a local surface plasmon is excited and thus an electric field enhancement effect is obtained. Also, a large amount of electrons are excited to the conduction band of TiO₂ composing the shell 14b by the enhancement electric field to pass through the porous electrode 5, thereby reaching the transparent conductive layer 2. In such a way, when the light is made incident to the porous electrode 5, not only the electron generated due to the excitation of the photosensitized dye reaches the transparent conductive layer 2, but also the electron excited to the conduction band of TiO₂ composing the shell 14b by excitation of the local surface plasmon on the surface of the core 14a of the metal/metal oxide fine particles 14 reaches the transparent conductive layer 2. For this reason, it is possible to obtain the high photoelectric conversion efficiency.

On the other hand, the photosensitizing dye from which the electron is lost receives an electron from a reducing agent in the electrolytic solution with which the porous electrode 5 or the like is impregnated, for example, I⁻ in the electrolytic solution in accordance with the following reaction to generate an oxidizing agent, for example, I₃⁻ (a union of I₂ and I⁻) in the electrolytic solution:

2I⁻→I₂+2e⁻

I₂+I⁻→I₃⁻

The oxidizing agent thus generated reaches the counter electrode 8 due to the diffusion, and receives the electron from the counter electrode 8 in accordance with a reverse reaction of the reaction described above to be reduced to the original reducing agent:

I₃⁻→I₂+I⁻

I₂+2e⁻→2I⁻

After the electron sent from the transparent conductive layer 2 to an external circuit has made an electrical work in the external circuit, the electron returns back to the counter electrode 8. In such a way, the optical energy is converted into the electrical energy without leaving any of the changes in the electrolytic solution as well as in the photosensitizing dye.

According to the sixth embodiment of the present disclosure, in addition to the same effects as those in the first embodiment, the following effects can be obtained. That is to say, the porous electrode 5 is composed of the metal/metal oxide particles 14 each having the core/shell structure composed of the spherical core 14a made of the metal, and the shell 14b made of the metal oxide and surrounding the circumference of the spherical core 14a. For this reason, when the porous electrode 5 or the like is impregnated with the electrolytic solution, the electrolyte of the electrolytic solution is prevented from contacting the spherical core 14a made of the metal of each of the metal/metal oxide fine particles 14, and thus the porous electrode 5 can be prevented from being dissolved due to the electrolyte. Therefore, gold, silver, copper or the like showing the surface plasmon resonance can be used as the metal composing the spherical core 14a of the metal of each of the metal/metal oxide fine particles 14, and thus it is possible to sufficiently obtain the effect of the surface plasmon resonance. In addition, the iodine system electrolyte can be used as the electrolyte of the electrolytic solution. With that, it is possible to obtain the dye-sensitized photoelectric conversion element having the large photoelectric conversion efficiency. Also, the excellent dye-sensitized photoelectric conversion element is used, thereby making it possible to manufacture a high-performance electronic apparatus.

### 7. Seventh Embodiment

### Photoelectric Conversion Element

A photoelectric conversion element according to a seventh embodiment of the present disclosure has the same structure as that of the dye-sensitized photoelectric conversion element according to the sixth embodiment of the present disclosure except that no photosensitizing dye is coupled to any of the metal/metal oxide fine particles 14 composing the porous electrode 5.

### [Method of Manufacturing Photoelectric Conversion Element]

A method of manufacturing the photoelectric conversion element is the same as that of manufacturing the dye-sensitized photoelectric conversion element according to the sixth embodiment of the present disclosure except that no photosensitizing dye is adsorbed on the porous electrode 5.

### [Operation of Photoelectric Conversion Element]

Next, an operation of the photoelectric conversion element will be described in detail.

When the light is made incident to the photoelectric conversion element, the photoelectric conversion element operates as a cell with the counter electrode 8 and the transparent conductive layer 2 as a positive electrode and a negative electrode, respectively. The principles of the operation are as follows. Note that, in this case, it is supposed that an FTO is used as the material for the transparent conductive layer 2, Au is used as the material for the core 14a of each of the metal/metal oxide fine particles 14 composing the porous electrode 5, TiO₂ is used as the material for the shell 14b, and redox species of I⁻/I₃⁻ are used as a redox couple. However, the present disclosure is by no means limited thereto.

The light which is transmitted through both of the transparent substrate 1 and the transparent conductive layer 2 to be made incident to the surface of the core 14a made of Au of each of the metal/metal oxide fine particles 14 composing the porous electrode 5, whereby the local surface plasmon is excited, thereby obtaining the electric field enhancement effect. Also, a large amount of electrons are excited to the conduction band of TiO₂ composing the shall 14b by the enhanced electric field to pass through the porous electrode 5, thereby reaching the transparent conductive layer 2.

On the other hand, the porous electrode 5 from which the electron is lost receives an electron from a reducing agent in the electrolytic solution with which the porous electrode 5 or the like is impregnated, for example, I⁻ in accordance with the following reaction to generate an oxidizing agent, for example, I₃⁻ (a union of I₂ and I⁻) in the electrolytic solution:

2I⁻→I₂+2e⁻

I₂+I⁻→I₃⁻

The oxidizing agent thus generated reaches the counter electrode 8 due to the diffusion, and receives the electron from the counter electrode 8 in accordance with a reverse reaction of the reaction described above to be reduced to the original reducing agent:

I₃⁻→I₂+I⁻

I₂+2e⁻→2I⁻

After the electron sent from the transparent conductive layer 2 to an external circuit has made an electrical work in the external circuit, the electron returns back to the counter electrode 8. In such a way, the optical energy is converted into the electrical energy without leaving any of the changes in the electrolytic solution.

According to the seventh embodiment of the present disclosure, it is possible to obtain the same advantages as those in the first embodiment.

### 8. Eighth Embodiment

### Electronic Apparatus

An electronic apparatus according to an eighth embodiment of the present disclosure includes at least one dye-sensitized photoelectric conversion element, according to the first embodiment of the present disclosure having the structure in which the electrolyte layer 10 is provided between the porous electrode 5 provided on the transparent substrate 1 through the transparent conductive layer 2, and the counter electrode 8. In this case, the current-collecting wiring 3 made with the conductive paste containing therein the metal particles and the low-melting point glass frit is provided on the transparent substrate 1 through the transparent conductive layer 2.

The dye-sensitized photoelectric conversion element of the first embodiment can be used as a power source for various kinds of electronic apparatuses. The electronic apparatus may be basically any kind of one, and includes both of mobile type one and stationary type one. Concrete examples are given as a mobile phone, a mobile apparatus, a robot, a personal computer, a car-mounted apparatus, various kinds of home electric appliances, and the like.

It is noted that the electronic apparatus including at least one dye-sensitized photoelectric conversion element of the first embodiment has been described, the electronic apparatus, for example, can also include at least one dye-sensitized photoelectric conversion element of any of the second to sixth embodiments or at least one photoelectric conversion element of the seventh embodiment.

Although the embodiments and Examples have been concretely described so far, the present disclosure is by no means limited thereto, and thus various kinds of changes can be made.

For example, the numerical values, structures, compositions, shapes, materials, and the like which have been given in the embodiments and Examples described above are merely exemplified, and thus numerical values, structures, compositions, shapes, materials, and the like which are different from those, respectively, may also be used as may be necessary.

In addition, any two or more of the first to seventh embodiments may be combined with each other as may be necessary.

It is noted that each of the pattern shapes of the current-collecting wirings 3 in the dye-sensitized photoelectric conversion elements according to the third to fifth embodiments of the present disclosure is also effectively applied not only to the dye-sensitized photoelectric conversion element or photoelectric conversion element using the porous electrode, but also to an amorphous silicon solar cell, a polycrystalline silicon solar cell, a single crystalline silicon solar cell, a compound semiconductor solar cell or the like. In addition, the current-collecting wiring 3 in each of the dye-sensitized photoelectric conversion elements according to the third to fifth embodiments of the present disclosure not only is made with the conductive paste containing therein the Ag particles and the low-melting point glass frit, but also may be formed by patterning a film formed by utilizing a vacuum evaporation method, a sputtering method or the like by carrying out etching.

The present application contains subject matter related to that disclosed in Japanese Priority Patent Application JP 2011-078413 filed in the Japan Patent Office on Mar. 31, 2011, the entire content of which is hereby incorporated by reference.

What is claimed is:

1. A method of manufacturing a photoelectric conversion element, comprising:
forming a current-collecting wiring with a conductive paste containing therein silver particles and a low-melting point glass frit on a transparent conductive substrate when said photoelectric conversion element having a structure in which an electrolyte layer is provided between a porous electrode on said transparent conductive substrate, and a counter substrate is manufactured.

2. The method of manufacturing a photoelectric conversion element according to claim 1, wherein a softening point of said low-melting point glass frit is from 360° C. to 500° C.

3. The method of manufacturing a photoelectric conversion element according to claim 2, wherein the softening point of said low-melting point glass frit is from 380° C. to 480° C.

4. The method of manufacturing a photoelectric conversion element according to claim 3, wherein the low-melting point glass frit is a glass frit containing therein a bismuth oxide, a boron oxide, a zinc oxide, and an aluminum oxide each having a softening point from 380° C. to 400° C., a glass frit containing therein a bismuth oxide, a zinc oxide, and a boron oxide each having a softening point from 440° C. to 460° C., a glass frit containing therein a bismuth oxide, a boron oxide, a zinc oxide, a copper oxide, and a silicon oxide each having a softening point from 450° C. to 470° C., or a glass frit containing therein a bismuth oxide, a zinc oxide, a boron oxide, and a silicon oxide each having a softening point from 460° C. to 480° C.

5. The method of manufacturing a photoelectric conversion element according to claim 1, wherein said photoelectric conversion element is a dye-sensitized photoelectric conversion element in which a photosensitized dye is coupled to said porous electrode.

6. A photoelectric conversion element having a structure in which an electrolyte layer is provided between a porous electrode on a transparent conductive substrate, and a counter substrate,
wherein a current-collecting wiring made with a conductive paste containing therein metal particles and a low-melting point glass frit is provided on said transparent conductive substrate.

7. The photoelectric conversion element according to claim 6, wherein a softening point of said low-melting point glass frit is from 360° C. to 500° C.

8. The photoelectric conversion element according to claim 7, wherein the softening point of said low-melting point glass frit is from 380° C. to 480° C.

9. The photoelectric conversion element according to claim 8, wherein the low-melting point glass frit is a glass frit containing therein a bismuth oxide, a boron oxide, a zinc oxide, and an aluminum oxide each having a softening point from 380° C. to 400° C., a glass frit containing therein a bismuth oxide, a zinc oxide, and a boron oxide each having a softening point from 440° C. to 460° C., a glass frit containing therein a bismuth oxide, a boron oxide, a zinc oxide, a copper oxide, and a silicon oxide each having a softening point from 450° C. to 470° C., or a glass frit containing therein a bismuth oxide, a zinc oxide, a boron oxide, and a silicon oxide each having a softening point from 460° C. to 480° C.

10. The photoelectric conversion element according to claim 6, wherein said photoelectric conversion element is a dye-sensitized photoelectric conversion element in which a photosensitized dye is coupled to said porous electrode.

11. The photoelectric conversion element according to claim 6, wherein said transparent conductive substrate is composed of a substrate in which a transparent conductive layer made of a fluorine-doped tin oxide is provided on a transparent substrate, and said current-collecting wiring is provided on said transparent conductive substrate through a conductive adhesion layer.

12. The photoelectric conversion element according to claim 11, wherein said adhesion layer is made of at least one kind of metal selected from the group consisting of silver, gold, platinum, titanium, chromium, aluminum, and copper.

13. The photoelectric conversion element according to claim 6, wherein said current-collecting wiring is composed of a bus electrode and plural finger electrodes branching off from said bus electrode, and when let t (m) be a width of at least one finer electrode, t fulfills the following expression:
$$t = {d}_{0} {i}_{0} y \times \sqrt{\frac{{ρ}_{0}}{{h}_{0} {W}_{0}}}$$
where d₀ is a power generation electrode width (an interval of said finger electrodes) (m), i₀ is a rated generated power current density (A/m²), y is a distance (m) from a terminal of the finger electrode, ρ₀ is volume resistivity (Ωm) of a material of each of said finger electrodes, h₀ is a thickness (m) of each of said finger electrodes, and W₀ is a generated power output density (W/m²).

14. The photoelectric conversion element according to claim 6, wherein said current-collecting wiring is composed of a bus electrode and plural stripe electrodes branching off from said bus electrode, and when let d₀ (m) be a pitch of said stripe electrodes, d₀ fulfills the following expression:
$${d}_{0} = \sqrt{\frac{3 t {W}_{0}}{{R}_{0} {i}_{0}^{2} {l}^{2}} + {t}^{2}}$$
where t is a width (m) of each of said stripe electrodes, W₀ is a rated generated power output density (W/m²), R₀ is a line resistance (Ω/m) of each of said stripe electrodes, i₀ is a rated generated power current density (A/m²), and l is a power-collecting distance (m) of each of said stripe electrodes.

15. The photoelectric conversion element according to claim 6, wherein said current-collecting wiring is composed of a bus electrode, and a mesh electrode or a grid electrode electrically connected to said bus electrode, and when let Ap be an aperture ratio of said mesh electrode or said grid electrode, Ap fulfills the following expression:
$$Ap = \frac{1}{\sqrt{\frac{3 t {W}_{0}}{{R}_{0} {i}_{0}^{2} {l}^{2} {t}^{2}} + 1}}$$
where t is a width (m) of each of said stripe electrodes, W₀ is a rated generated power output density (W/m²), R₀ is a line resistance (Ω/m) of each of said stripe electrodes, i₀ is a rated generated power current density (A/m²), and l is a power-collecting distance (m) of each of said stripe electrodes.

16. An electronic apparatus, comprising:
at least one photoelectric conversion element,
wherein said at least one photoelectric conversion element is a photoelectric conversion element(s) (each of) which has a structure in which an electrolyte layer is provided between a porous electrode on a transparent conductive substrate, and a counter substrate, and in which
a current-collecting wiring made with a conductive paste containing therein metal particles and a low-melting point glass frit is provided on said transparent conductive substrate.
